(19) United States
(12) Patent Application Publication
(10) Pub. No.: US 2025/0368866 A1
(43) Pub. Date: Dec. 4, 2025

(54) ADHESIVE SHEET, ADHESIVE SHEET WITH RELEASE FILM, LAMINATE FOR IMAGE DISPLAY DEVICE, FLEXIBLE IMAGE DISPLAY DEVICE, AND ADHESIVE SHEET FOR CONSTITUENT MEMBER OF FLEXIBLE IMAGE DISPLAY DEVICE

(71) Applicant: MITSUBISHI CHEMICAL CORPORATION, Tokyo (JP)

(72) Inventors: Ryuichiro HASHIMOTO, Tokyo (JP); Mayuka USHIJIMA, Tokyo (JP)

(73) Assignee: MITSUBISHI CHEMICAL CORPORATION, Tokyo (JP)

(21) Appl. No.: 19/303,158

(22) Filed: Aug. 18, 2025

Related U.S. Application Data
(63) Continuation of application No. PCT/JP2024/001556, filed on Jan. 22, 2024.

(30) Foreign Application Priority Data
Mar. 6, 2023 (JP) 2023-033780

(51) Int. Cl. C09J 133/08; C09J 163/00; H10K 77/10; H10K 102/00

(52) U.S. Cl. CPC C09J 133/08; C09J 163/00; H10K 77/111; H10K 2102/311

(57) ABSTRACT

As an adhesive sheet formed from an adhesive composition including an acrylic polymer (A) containing no carboxy group, a photoinitiator (B), and an epoxy compound (C).

### RELATED APPLICATIONS

This application is a continuation of International Application No. PCT/JP2024/001556, filed on Jan. 22, 2024, which claims priority to Japanese Patent Application No. 2023-033780, filed on Mar. 6, 2023, the entire contents of each of which are herein incorporated by reference.

### TECHNICAL FIELD

The present disclosure relates to an adhesive sheet, an adhesive sheet with a release film, a laminate for an image display device, a flexible image display device, and an adhesive sheet for a constituent member of a flexible image display device. More particularly, the present disclosure relates to an adhesive sheet, an adhesive sheet with a release film, a laminate for an image display device, a flexible image display device, and an adhesive sheet for a constituent member of a flexible image display device, each having sufficient adhesiveness and/or flexibility.

### BACKGROUND ART

In recent years, flexible image display devices using an organic light-emitting diode (OLED) and a quantum dot (QD) have been developed and widely put into commercial use.

Examples of the flexible image display devices include a bendable device with an image display surface having a curved shape, a foldable device capable of being repeatedly folded, a rollable device capable of being rolled, a stretchable device which is expandable and shrinkable, etc.

Such image display device has a laminate structure in which a plurality of member sheets, such as a surface protective film, a cover lens, a circularly polarization plate, a touch film sensor, and a light-emitting element, is pasted together by a transparent adhesive sheet, and each of the laminate structures can be regarded as a laminated sheet in which the member sheet and the adhesive sheet are laminated together.

Foldable and flexible display devices have various problems caused by interlayer stress when folded. For example, there is a need for a laminated sheet that can quickly recover to a flat state when a screen in a folded state is opened, without leaving any effect caused by being placed in a bent state.

Moreover, repeated folding operation may cause peeling off of an adhesive sheet or cracks and eventually breakage due to stress applied to a member as an adherend. A laminated sheet is also required to be durable against repeated folding operation particularly under severe conditions, namely at low temperature.

For such adhesive sheet of a flexible image display device, flexibility and particularly high durability against bending, not to mention optical properties, are necessary.

For example, PTL 1 discloses a laminate film with an adhesive layer, which has no risk of causing disturbance in an image to be displayed on a folded portion after repeated bending.

Furthermore, PTL 2 discloses a laminate including a double-sided adhesive sheet that does not suffer flexure or exfoliation even in a flexing test closer to the actual use environment, the double-sided adhesive sheet having a glass transition temperature and a storage elastic modulus each in a predetermined range; and a flexible member for an image display device.

### RELATED ART DOCUMENT

### Patent Document

PTL 1: JP-A-2020-196255
PTL 2: WO-A-2018/173896

### SUMMARY

### Problems to be Solved by the Disclosure

A wide variety of materials are used for a flexible member for an image display device, besides an adhesive sheet. In addition, the flexible member may be coated by surface treatment to prevent flexure and breakage. An adhesive sheet for integrating such member sheet should have stable adhesion to a wide variety of materials.

However, in the techniques disclosed in PTL 1 and PTL 2, adhesion to a flexible member has not been considered.

Accordingly, in view of the circumstance, the present disclosure provides an adhesive sheet, an adhesive sheet with a release film, a laminate for an image display device, a flexible image display device, and an adhesive sheet for a constituent member of a flexible image display device, each having an excellent adhesive property to a flexible member, particularly polyimide, as well as excellent flexibility.

### Means for Solving the Problems

Accordingly, in view of the circumstance, the present inventors have found that an adhesive sheet formed from an adhesive composition including an acrylic polymer containing no carboxy group, a photoinitiator, and an epoxy compound can be provided with excellent adhesion to a flexible member as well as flexibility due to a storage shear modulus set in a specific range or a ratio of adhesion to polyimide between 23° C. and 60° C. set in a specific range.

Specifically, the present disclosure has the following aspects.

[1] An adhesive sheet formed from an adhesive composition including an acrylic polymer (A) containing no carboxy group, a photoinitiator (B), and an epoxy compound (C),
wherein the adhesive sheet has a storage shear modulus at 25° C. (G′ (25° C.)) equal to or less than 60 kPa as determined by dynamic viscoelasticity measurement with a shearing mode at a frequency of 1

### Hz.

[2] An adhesive sheet formed from an adhesive composition including an acrylic polymer (A) containing no carboxy group, a photoinitiator (B), and an epoxy compound (C),
wherein the adhesive sheet has a ratio (P(23° C.)/P(60° C.)) of adhesion to polyimide at 23° C. (P(23° C.)) to adhesion to polyimide at 60° C. (P(60° C.)) of 0.3 to 2.6.
   [3] The adhesive sheet according to [2], wherein the adhesion to polyimide at 23° C. (P(23° C.)) is equal to or more than 3.5 N/cm, and the adhesion to polyimide at 60° C. (P(60° C.)) is equal to or more than 1.5 N/cm.
   [4] The adhesive sheet according to any one of [1] to [3], wherein in Hansen solubility parameters (δD, δP, δH), a Hansen solubility parameter distance (Ra) between Hansen solubility parameters of the epoxy compound (C) and Hansen solubility parameters of the acrylic polymer (A) containing no carboxy group is 2.0 to 10.0.
   [5] The adhesive sheet according to any one of [1] to [4], wherein the epoxy compound (C) has a polar term δP equal to or more than 4.5 MPa^{0.5}, and a hydrogen bond term δH equal to or more than 4.0 MPa^{0.5} in Hansen solubility parameters (δD, δP, δH) calculated by a Y-MB method.
   [6] The adhesive sheet according to any one of [1] to [5], wherein the epoxy compound (C) is a polyfunctional epoxy compound.
   [7] The adhesive sheet according to any one of [1] to [6], wherein the epoxy compound (C) is an epoxy compound including an alkylene glycol backbone.
   [8] The adhesive sheet according to any one of [1] to [7], wherein the epoxy compound (C) is an epoxy compound including an alkylene glycol backbone, the number of repeating units thereof being 2 to 30.
   [9] The adhesive sheet according to any one of [1] to [8], wherein the epoxy compound (C) is an epoxy compound including a linear alkylene glycol backbone.

The adhesive sheet according to any one of [1] to [9], wherein the epoxy compound (C) is an epoxy compound having a weight-average molecular weight of 200 to 1000.

The adhesive sheet according to any one of [1] to [10], wherein the epoxy compound (C) is an epoxy compound having an epoxy equivalent weight of 80 to 500.

The adhesive sheet according to any one of [1] to [11], wherein the epoxy compound (C) is contained in an amount of 0.01 to 10 parts by mass relative to 100 parts by mass of the acrylic polymer (A) containing no carboxy group.

The adhesive sheet according to any one of [1] to [12], wherein the adhesive composition includes a radically polymerizable compound (D).

The adhesive sheet according to [13], wherein the radically polymerizable compound (D) includes an alkylene glycol backbone.

The adhesive sheet according to or [14], wherein the radically polymerizable compound (D) includes a urethane bond.

The adhesive sheet according to any one of [1] to [15], including a hydrogen abstraction-type photoinitiator (b1) as the photoinitiator (B).

The adhesive sheet according to any one of [1] to [16], wherein the acrylic polymer (A) containing no carboxy group is an acrylic polymer including a structural site derived from a (meth)acrylate (a1) containing an alkyl group having 3 or more carbon atoms, and a structural site derived from a hydroxyl group-containing (meth)acrylate (a2).

The adhesive sheet according to any one of [1] to [17], wherein the adhesive sheet has a storage shear modulus at −30° C. (G′(−30° C.)) equal to or less than 1200 kPa as determined by dynamic viscoelasticity measurement with a shearing mode at a frequency of 1 Hz.

The adhesive sheet according to any one of [1] to [18], wherein the adhesive sheet has a glass transition temperature (Tg) equal to or lower than −20° C., the glass transition temperature (Tg) being defined by a maximum value of Tan δ as determined by dynamic viscoelasticity measurement with a shearing mode at a frequency of 1 Hz.

The adhesive sheet according to any one of [1] to [19], wherein the adhesive sheet has a recovery rate equal to or more than 60% calculated by the following expression based on a thickness of 0.5 to 1.2 mm, a strain (γₘₐₓ) after applying 400% strain at a temperature of 25° C. for 600 seconds, and a strain (γₘᵢₙ) 600 seconds after stress unloading.

$$recovery rate ( \% ) = [ ( {γ}_{max} - {γ}_{min} ) / {γ}_{max} ] \times 100$$

The adhesive sheet according to any one of [1] to [20], wherein the adhesive sheet has a gel fraction of 30 to 95%.

The adhesive sheet according to any one of [1] to [21], wherein the adhesive sheet has a total light transmittance equal to or more than 80% and a Haze equal to or less than 5%.

An adhesive sheet with a release film, including the adhesive sheet according to any one of [1] to [22] and a release film, wherein the adhesive sheet and the release film are laminated together.

A laminate for an image display device, including two constituent members of an image display device and the adhesive sheet according to any one of [1] to [22], wherein the two constituent members of an image display device are laminated via the adhesive sheet.

A flexible image display device including the laminate for an image display device according to [24].

An adhesive sheet for a constituent member of a flexible image display device, including the adhesive sheet according to any one of [1] to [22].

### Effects of the Disclosure

The adhesive sheet of the present disclosure has not only excellent adhesion to a flexible member, particularly polyimide, but also excellent flexibility. Accordingly, the adhesive sheet of the present disclosure can be suitably used as an adhesive sheet for use in a flexible image display device.

### EMBODIMENTS OF THE DISCLOSURE

Hereinafter, one exemplary embodiment of the present disclosure will be described in detail. However, the present disclosure is not limited to the embodiment described below.

Note that “film” in the present disclosure conceptually encompasses sheet, film, and tape.

In addition, the expression “panel,” such as image display panel and protection panel, is intended to encompass plate, sheet, and film.

In the present disclosure, the expression “x to y” (x and y are given numbers) is intended to encompass the meaning of “preferably more than x” or “preferably less than y” unless otherwise specified, in addition to the meaning of “x or more and y or less.”

Further, the expression “x or more” or “equal to or more than x” (x is a given number) is intended to encompass the meaning of “preferably more than x” unless otherwise specified, and the expression “y or less” or “equal to or less than y” (y is a given number) is intended to encompass the meaning of “preferably less than y” unless otherwise specified.

Yet further, the expression “x and/or y” (x and y are each a given configuration) is intended to mean at least one of x and y, including the following three meanings: only x; only y; and x and y.

In the present disclosure, “(meth)acrylic” has a meaning encompassing acrylic and methacrylic, “(meth)acrylate” has a meaning encompassing acrylate and methacrylate, and “(meth)acryloyl” has a meaning encompassing acryloyl and methacryloyl.

Further, in the present disclosure, “main component” means a component that has a significant effect on the properties of the material, and the component content is usually 40% by mass or more, preferably 50% by mass or more, more preferably 60% by mass or more, and particularly preferably 70% by mass or more of the entire material.

An adhesive sheet according to an exemplary embodiment of the present disclosure (hereinafter referred to as “the present adhesive sheet 1”) is an adhesive sheet formed from an adhesive composition including an acrylic polymer (A) containing no carboxy group, a photoinitiator (B), and an epoxy compound (C), wherein the adhesive sheet has a storage shear modulus at 25° C. (G′ (25° C.)) equal to or less than 60 kPa as determined by dynamic viscoelasticity measurement with a shearing mode at a frequency of 1 Hz.

Furthermore, an adhesive sheet according to an exemplary embodiment of the present disclosure (hereinafter referred to as “the present adhesive sheet 2”) is an adhesive sheet formed from an adhesive composition including an acrylic polymer (A) containing no carboxy group, a photoinitiator (B), and an epoxy compound (C), wherein the adhesive sheet has a ratio (P(23° C.)/P(60° C.)) of adhesion to polyimide at 23° C. (P(23° C.)) to adhesion to polyimide at 60° C. (P(60° C.)) of 0.3 to 2.6.

Hereinafter, the present adhesive sheets 1 and 2 (hereinafter may be simply referred to as “the present adhesive sheet”) will be described.

### [Acrylic Polymer (a) Containing No Carboxy Group]

The acrylic polymer (A) containing no carboxy group [hereinafter may be referred to as “the acrylic polymer (A)”] generally contains no carboxy group, but includes a structural site derived from a (meth)acrylate (a1) containing an alkyl group having 3 or more carbon atoms [hereinafter may be referred to as “alkyl (meth)acrylate (a1)”]. Above all, the acrylic polymer (A) used in the present adhesive sheets 1 and 2 preferably includes the structural site derived from the alkyl (meth)acrylate (a1) and a structural site derived from a hydroxyl group-containing (meth)acrylate (a2). Furthermore, the acrylic polymer (A) may be used alone or in combination of two or more kinds thereof.

Such acrylic polymer (A) can usually be obtained by polymerizing a copolymerization component containing the alkyl (meth)acrylate (a1) and the hydroxyl group-containing (meth)acrylate (a2).

Additionally, the acrylic polymer (A) may include, for example, a structural site derived from at least one copolymerizable monomer (a3) [hereinafter referred to as “copolymerizable monomer (a3)”] selected from a group consisting of a (meth)acrylate containing an alkyl group having 1 or 2 carbon atoms and a vinyl ester monomer, a structural site derived from a functional group-containing ethylenically unsaturated monomer (a4), and a structural site derived from another copolymerizable monomer (a5), besides the structural site derived from the alkyl (meth)acrylate (a1) and the structural site derived from the hydroxyl group-containing (meth)acrylate (a2).

That is, the copolymerization component may contain components other than the alkyl (meth)acrylate (a1) and the hydroxyl group-containing (meth)acrylate (a2), for example, the copolymerizable monomer (a3), the functional group-containing ethylenically unsaturated monomer (a4), and the other copolymerizable monomer (a5).

Additionally, the acrylic polymer (A) preferably includes no structural site derived from a carboxy group-containing (meth)acrylate in view of adhesiveness, moisture and heat resistance, and a corrosive effect on a base material.

[Alkyl (Meth)acrylate (a1)]

Examples of the alkyl (meth)acrylate (a1) include: linear alkyl (meth)acrylates such as n-propyl (meth)acrylate, n-butyl (meth)acrylate, n-pentyl (meth)acrylate, n-hexyl (meth)acrylate, n-heptyl (meth)acrylate, n-octyl (meth)acrylate, n-nonyl (meth)acrylate, n-decyl (meth)acrylate, lauryl (meth)acrylate, n-tridecyl (meth)acrylate, stearyl (meth)acrylate, icosyl (meth)acrylate, heneicosyl (meth)acrylate, and behenyl (meth)acrylate; branched alkyl (meth)acrylates such as isopropyl (meth)acrylate, isobutyl (meth)acrylate, sec-butyl (meth)acrylate, t-butyl (meth)acrylate, isopentyl (meth)acrylate, neopentyl (meth)acrylate, 2-ethylhexyl (meth)acrylate, isooctyl (meth)acrylate, isononyl (meth)acrylate, isodecyl (meth)acrylate, isostearyl (meth)acrylate, and isoicosyl (meth)acrylate; alicyclic (meth)acrylates such as cyclohexyl (meth)acrylate, t-butylcyclohexyl (meth)acrylate, isobornyl (meth)acrylate, 3,3,5-trimethylcyclohexyl (meth)acrylate, and adamantyl (meth)acrylate; and the like. One kind or a combination of two or more kinds thereof may be used.

Among them, linear alkyl (meth)acrylates are preferred in view of adhesiveness and recovering ability.

Further, from the viewpoint of a balance between adhesiveness and bendability at low temperature, preferred is a linear or branched alkyl (meth)acrylate containing an alkyl group having 3 to 18 carbon atoms, further preferably an alkyl group having 3 to 16 carbon atoms, particularly preferably an alkyl group having 3 to 12 carbon atoms, and especially preferably an alkyl group having 3 to 8 carbon atoms. Specific examples thereof include n-propyl (meth)acrylate, n-butyl (meth)acrylate, n-pentyl (meth)acrylate, n-hexyl (meth)acrylate, n-octyl (meth)acrylate, n-nonyl (meth)acrylate, decyl (meth)acrylate, 2-ethylhexyl (meth)acrylate, and the like. Among them, n-butyl (meth)acrylate and 2-ethylhexyl (meth)acrylate are preferred.

Yet further, the alkyl (meth)acrylate (a1) is particularly preferably acrylate from the viewpoint of suppressing the increase in a storage shear modulus (G′) at low temperature to improve bendability.

In the acrylic polymer (A), the structural site derived from the alkyl (meth)acrylate (a1) is contained in an amount of generally 40 to 95% by mass, preferably 45 to 90% by mass, and particularly preferably 50 to 85% by mass relative to the amount of the acrylic polymer (A) in view of suppression of the increase in the storage shear modulus (G′) at low temperature. This is preferable because the amount of the structural site derived from the alkyl (meth)acrylate (a1) equal to or more than the lower limit value enables to suppress the increase in the storage shear modulus (G′) at low temperature, whereas the amount equal to or less than the upper limit value can achieve compatibility with other physical properties such as adhesiveness.

[Hydroxyl Group-Containing (Meth)acrylate (a2)]

Examples of the hydroxyl group-containing (meth)acrylate (a2) include: hydroxyalkyl (meth)acrylates such as 2-hydroxyethyl (meth)acrylate, 4-hydroxybutyl (meth)acrylate, 5-hydroxypentyl (meth)acrylate, 6-hydroxyhexyl (meth)acrylate, and 8-hydroxyoctyl (meth)acrylate; caprolactone-modified hydroxy (meth)acrylates such as caprolactone-modified 2-hydroxyethyl (meth)acrylate; (meth)acrylates having an oxyalkylene glycol structure, such as diethylene glycol (meth)acrylate, polyethylene glycol (meth)acrylate, polypropylene glycol (meth)acrylate, polytetramethylene glycol (meth)acrylate, and polyoxyethylene polyoxypropylene glycol (meth)acrylate; primary hydroxyl group-containing (meth)acrylates such as 2-acryloyloxyethyl-2-hydroxyethyl phthalate; secondary hydroxyl group-containing (meth)acrylates such as 2-hydroxypropyl (meth)acrylate, 2-hydroxybutyl (meth)acrylate, and 3-chloro-2-hydroxypropyl (meth)acrylate; tertiary hydroxyl group-containing (meth)acrylates such as 2,2-dimethyl 2-hydroxyethyl (meth)acrylate; and the like. One kind or a combination of two or more kinds thereof can be used.

Among the hydroxyl group-containing (meth)acrylates (a2), preferred from the viewpoint of decreasing the storage shear modulus (G′) at low temperature is a hydroxyl group-containing (meth)acrylate containing a hydroxyalkyl group having 1 to 10 carbon atoms, further preferably 1 to 6 carbon atoms, and especially preferably 2 to 4 carbon atoms, for example, 2-hydroxyethyl (meth)acrylate, 4-hydroxybutyl (meth)acrylate, 2-hydroxypropyl (meth)acrylate, or the like. In particular, primary hydroxyl group-containing (meth)acrylates, for example, 2-hydroxyethyl (meth)acrylate and 4-hydroxybutyl (meth)acrylate are preferred, among which 4-hydroxybutyl (meth)acrylate is particularly preferred.

Furthermore, when 2-hydroxyethyl (meth)acrylate and 4-hydroxybutyl (meth)acrylate are used as the hydroxyl group-containing (meth)acrylate (a2), a ratio thereof [2-hydroxyethyl (meth)acrylate/4-hydroxybutyl (meth)acrylate] is preferably 95/5 to 30/70, further preferably 90/10 to 40/60, particularly preferably 85/15 to 45/55, and especially preferably 80/20 to 50/50 on a mass basis. The excessively small amount of the 2-hydroxyethyl (meth)acrylate results in reduced adhesion during use thereof as an adhesive, whereas the excessively large amount thereof tends to decrease bending durability during use thereof as an adhesive.

Note that in the hydroxyl group-containing monomer (a2), an amount of di(meth)acrylate as an impurity contained in the hydroxyl group-containing monomer (a2) is preferably as small as possible. Specifically, the amount equal to or less than 0.5% by mass is preferable for use, or the amount is particularly preferably 0.2% by mass or less, and further preferably 0.1% by mass or less.

In the acrylic polymer (A), the structural site derived from the hydroxyl group-containing monomer (a2) is contained in an amount of generally 5 to 60% by mass, preferably 8 to 45% by mass, particularly preferably 10 to 35% by mass, further preferably 11 to 30% by mass, and especially preferably 12 to 25% by mass relative to the amount of the acrylic polymer (A).

If the amount is too small, moisture and heat resistance tends to decrease during use thereof as an adhesive. If the amount is too large, the acrylic polymer (A) easily undergoes self-crosslinking reaction and heat resistance tends to decrease.

[Copolymerizable Monomer (a3)]

In the present disclosure, it is preferable to further contain the copolymerizable monomer (a3) as the copolymerization component in view of improving cohesive force and also adhesion during use thereof as an adhesive.

Examples of the copolymerizable monomer (a3) include: (meth)acrylates containing an alkyl group having 1 or 2 carbon atoms, such as methyl (meth)acrylate and ethyl (meth)acrylate; vinyl ester monomers such as vinyl formate, vinyl acetate, vinyl propionate, vinyl valerate, vinyl butyrate, vinyl isobutyrate, and vinyl pivalate; and the like. These copolymerizable monomers (a3) can be used alone or in combination of two or more. Among them, in view of improving cohesive force during use thereof as an adhesive, (meth)acrylates containing an alkyl group having 1 or 2 carbon atoms are preferred, and ethyl (meth)acrylate is particularly preferred.

When the acrylic polymer (A) includes the structural site derived from the copolymerizable monomer (a3), the amount thereof is generally preferably 1 to 70% by mass, particularly preferably 3 to 60% by mass, and further preferably 5 to 45% by mass relative to the amount of the acrylic polymer (A). If the amount of the copolymerizable monomer (a3) is too small, adhesion tends to decrease during use thereof as an adhesive. If the amount is too large, durability tends to decrease during use of the acrylic polymer (A) having a small weight-average molecular weight as an adhesive.

Furthermore, when methyl (meth)acrylate and/or ethyl (meth)acrylate is used as the copolymerizable monomer (a3), the amount of the structural site derived from the methyl (meth)acrylate and/or ethyl (meth)acrylate in the acrylic polymer (A) is generally 5 to 40% by mass, preferably 7 to 30% by mass, and further preferably 10 to 25% by mass relative to the amount of the acrylic polymer (A). The excessively large amount of the structural site derived from the methyl (meth)acrylate and/or ethyl (meth)acrylate tends to reduce handleability during processing due to increased viscosity. The excessively small amount thereof tends to cause a decrease in adhesion during use thereof as an adhesive.

[Functional Group-Containing Ethylenically Unsaturated Monomer (a4)]

In the present adhesive sheet, the functional group-containing ethylenically unsaturated monomer (a4) (except for the hydroxyl group-containing monomer (a2)) can be used as the copolymerization component of the acrylic polymer (A) as necessary.

Examples of the functional group-containing ethylenically unsaturated monomer (a4) include a functional group-containing monomer having a nitrogen atom, an acetoacetyl group-containing monomer, an isocyanate group-containing monomer, a glycidyl group-containing monomer, and the like.

Among them, in view of imparting cohesive force and facilitation of crosslinking, the functional group-containing monomer having a nitrogen atom is preferred. An amino group-containing monomer and an amide-group containing monomer are further preferred, among which the amino group-containing monomer is particularly preferred.

Examples of the amino group-containing monomer include: primary amino group-containing (meth)acrylates such as aminomethyl (meth)acrylate and aminoethyl (meth)acrylate; secondary amino group-containing (meth)acrylates such as t-butylaminoethyl (meth)acrylate and t-butylaminopropyl (meth)acrylate; tertiary amino group-containing (meth)acrylates such as ethylaminoethyl (meth)acrylate, dimethylaminoethyl (meth)acrylate, diethylaminoethyl (meth)acrylate, dimethylaminopropyl (meth)acrylate, diethylaminopropyl (meth)acrylate, and dimethylaminopropyl acrylamide; and the like.

Examples of the amide group-containing monomer include: (meth)acrylamide; N-alkyl (meth)acrylamides such as N-methyl (meth)acrylamide, N-ethyl (meth)acrylamide, N-propyl (meth)acrylamide, N-n-butyl (meth)acrylamide, diacetone (meth)acrylamide, and N,N′-methylenebis (meth)acrylamide; N,N-dialkyl (meth)acrylamides such as N, N-dimethyl (meth)acrylamide, N, N-diethyl (meth)acrylamide, N, N-dipropyl (meth)acrylamide, N, N-ethylmethyl acrylamide, and N,N-diallyl (meth)acrylamide; hydroxyalkyl (meth)acrylamides such as N-hydroxymethyl (meth)acrylamide and N-hydroxyethyl (meth)acrylamide; alkoxyalkyl (meth)acrylamides such as N-methoxymethyl (meth)acrylamide and N-(n-butoxymethyl) (meth)acrylamide; and the like.

Examples of the acetoacetyl group-containing monomer include 2-(acetoacetoxy)ethyl (meth)acrylate, allyl acetoacetate, and the like.

Examples of the isocyanate group-containing monomer include 2-(meth)acryloyloxyethyl isocyanate, alkylene oxide adducts thereof, etc.

Examples of the glycidyl group-containing monomer include glycidyl (meth)acrylate, allylglycidyl (meth)acrylate, and the like.

These functional group-containing ethylenically unsaturated monomers (a4) may be used alone or in combination of two or more.

When the acrylic polymer (A) includes the structural site derived from the functional group-containing ethylenically unsaturated monomer (a4), the amount thereof is generally 30% by mass or less, preferably 20% by mass or less, further preferably 10% by mass or less, and especially preferably 5% by mass or less relative to the amount of the acrylic polymer (A). The excessively large amount of the structural site derived from the functional group-containing ethylenically unsaturated monomer (a4) tends to reduce heat resistance of the acrylic polymer (A). Note that a lower limit is generally 0.1% by mass, preferably 1% by mass.

[Other Copolymerizable Monomer (a5)]

In the present adhesive sheet, as the copolymerization component of the acrylic polymer (A), the other copolymerizable monomer (a5) can be used as necessary.

Examples of the other copolymerizable monomer (a5) include: (meth)acrylates having an alkoxy alkylene glycol backbone, such as methoxy diethylene glycol (meth)acrylate, methoxy polyethylene glycol (meth)acrylate, butoxy polyethylene glycol (meth)acrylate, methoxy polypropylene glycol (meth)acrylate, butoxy polypropylene glycol (meth)acrylate, methoxy polytetramethylene glycol (meth)acrylate, butoxy polytetramethylene glycol (meth)acrylate, methoxy polyoxyethylene polyoxypropylene glycol (meth)acrylate, and butoxy polyoxyethylene polyoxypropylene glycol (meth)acrylate; aromatic (meth)acrylate monomers, such as phenyl (meth)acrylate, benzyl (meth)acrylate, phenoxyethyl (meth)acrylate, phenyl diethylene glycol (meth)acrylate, phenoxy polyethylene glycol (meth)acrylate, phenoxy polyethylene glycol-polypropylene glycol-(meth)acrylate, and nonylphenol ethylene oxide adduct (meth)acrylate; and monomers such as acrylonitrile, methacrylonitrile, styrene, α-methylstyrene, vinyl propionate, vinyl stearate, vinyl chloride, vinylidene chloride, alkyl vinyl ether, vinyltoluene, vinyl pyridine, vinyl pyrrolidone, dialkyl itaconate, dialkyl fumarate, allyl alcohol, acrylic chloride, methyl vinyl ketone, N-acrylamidemethyltrimethylammonium chloride, allyltrimethylammonium chloride, and dimethylallyl vinyl ketone. One kind or a combination of two or more kinds thereof can be used.

Furthermore, for the purpose of higher molecular weight of the acrylic polymer (A), for example, a small amount of a compound having two or more ethylenically unsaturated groups, such as ethylene glycol di(meth)acrylate, diethylene glycol di(meth)acrylate, triethylene glycol di(meth)acrylate, polyethylene glycol di(meth)acrylate, propylene glycol di(meth)acrylate, and divinyl benzene, etc. can also be used together. In this case, the compound having two or more of these ethylenically unsaturated groups has high reactivity, and usually does not remain unreacted when used as the polymerization component of the acrylic polymer (A). Note that if used in an excessively large amount, the compound having two or more of these ethylenically unsaturated groups will remain unreacted and tend to cause gelation of the acrylic polymer (A).

When the acrylic polymer (A) includes the structural site derived from the other copolymerizable monomer (a5), the amount thereof is generally 50% by mass or less, preferably 40% by mass or less, and further preferably 20% by mass or less relative to the amount of the acrylic polymer (A). The excessively large amount of the other copolymerizable monomer (a5) tends to reduce heat resistance or adhesion. Note that a lower limit is generally 0.1% by mass, preferably 1% by mass.

The acrylic polymer (A) used in the present adhesive sheets 1 and 2 can be obtained by appropriate selection and polymerization of the copolymerization component.

Examples of the polymerization method of the acrylic polymer (A) include conventionally known methods such as solution polymerization, suspension polymerization, bulk polymerization, and emulsion polymerization, among which solution polymerization is preferred in view of its ability to safely and stably produce the acrylic polymer (A) with any formulation monomer.

Hereinafter, an example of the preferable method for producing the acrylic polymer (A) used in the present disclosure will be described.

Firstly, the copolymerization component and a polymerization initiator are mixed with or added dropwise to an organic solvent, and solution polymerization is carried out to obtain an acrylic polymer solution.

### [Organic Solvent]

Examples of the organic solvent used for the polymerization reaction include: aromatic hydrocarbons such as toluene and xylene; aliphatic hydrocarbons such as hexane; esters such as ethyl acetate and butyl acetate; aliphatic alcohols such as N-propyl alcohol and isopropyl alcohol; ketones such as acetone, methyl ethyl ketone, methyl isobutyl ketone, and cyclohexanone; etc. One kind or a combination of two or more kinds thereof can be used. Among these solvents, ethyl acetate is preferred.

### [Polymerization Initiator]

As the polymerization initiator used for the polymerization reaction, common radical polymerization initiators such as azo polymerization initiators and peroxide polymerization initiators can be used. Examples of the azo polymerization initiator include 2,2′-azobis(2-methylbutyronitrile), 2,2′-azobisbutyronitrile, (1-phenylethyl)azodiphenyl methane, 2,2′-azobis(2,4-dimethylvaleronitrile), 2,2′-azobis(2-cyclopropyl propionitrile), 2,2′-azobis(4-methoxy-2,4-dimethylvaleronitrile), and the like. Examples of the peroxide polymerization initiator include benzoyl peroxide, di-t-butyl peroxide, cumene hydroperoxide, lauroyl peroxide, t-butyl peroxypivalate, t-hexyl peroxypivalate, t-hexyl peroxyneodecanoate, diisopropyl peroxycarbonate, diisobutyryl peroxide, and the like. One kind or a combination of two or more kinds thereof can be used. Among them, 2,2′-azobis(2,4-dimethylvaleronitrile) is preferred.

The polymerization initiator is used in an amount of generally 0.001 to 10 parts by mass, preferably 0.1 to 8 parts by mass, particularly preferably 0.5 to 6 parts by mass, further preferably 1 to 4 parts by mass, especially preferably 1.5 to 3 parts by mass, and the most preferably 2 to 2.5 parts by mass relative to 100 parts by mass of the copolymerization component. If the polymerization initiator is used in the excessively small amount, a reduced polymerization rate of the acrylic polymer (A) tends to increase residual monomers or increase the weight-average molecular weight of the acrylic polymer (A). If the use amount is too large, gelation of the acrylic polymer (A) is likely to occur as described later.

### [Polymerization Conditions, etc.]

Regarding polymerization conditions for the solution polymerization, the polymerization may be performed according to conventionally known polymerization conditions. For example, the polymerization component and the polymerization initiator can be mixed with or added dropwise to a solvent, and polymerized under predetermined polymerization conditions.

A polymerization temperature in the polymerization reaction is generally 40 to 120° C., but in the present disclosure, preferably 50 to 90° C., particularly preferably 55 to 75° C., and further preferably 60 to 70° C. in view of capability of stable reaction. If the polymerization temperature is too high, gelation of the acrylic polymer (A) is likely to occur. If the polymerization temperature is too low, reduced activity of the polymerization initiator tends to decrease a polymerization rate and increase residual monomers.

Furthermore, a polymerization time in the polymerization reaction (in a case of performing finishing heating as described later, a time until the start of the finishing heating) is not particularly limited, but preferably 0.5 hours or longer, particularly preferably 1 hour or longer, further preferably 2 hours or longer, and especially preferably 5 hours or longer after the final addition of the polymerization initiator. An upper limit of the polymerization time is generally 72 hours.

Note that the polymerization reaction is preferably performed under reflux of the solvent in view of ease of heat removal.

In the production of the acrylic polymer (A), in order to reduce the amount of the remaining polymerization initiator, the finishing heating is preferably used to decompose the polymerization initiator by heat.

The finishing heating is preferably performed at a temperature higher than a temperature at a half-life of 10 hours of the polymerization initiator. Specifically, the finishing heating temperature is generally 40 to 150° C., preferably 55 to 130° C. in view of preventing gelation, and particularly preferably 75 to 95° C. If the finishing heating temperature is too high, the acrylic polymer (A) tends to be yellowed. If the finishing heating temperature is too low, the polymerization component and the polymerization initiator tend to remain, causing decrease in stability over time and heat stability of the acrylic polymer (A).

In this manner, the acrylic polymer (A) can be obtained.

Furthermore, a photoactive site, for example, a polymerizable carbon double bond group, may be introduced into a side chain of the acrylic polymer (A). This can increase efficiency of crosslinking of the adhesive composition, such that the adhesive composition can be crosslinked for a shorter time and productivity can be increased.

An exemplary method for introducing the polymerizable carbon double bond group into the side chain of the acrylic polymer (A) includes: preparing a copolymer containing the hydroxyl group-containing (meth)acrylate (a2) and the functional group-containing ethylenically unsaturated monomer (a4) as described above; and thereafter subjecting a compound, which includes a functional group capable of reacting with these functional groups and a polymerizable carbon double bond group, to condensation or additional reaction while maintaining activity of the polymerizable carbon double bond group.

A combination of these functional groups can include an epoxy group (glycidyl group) and a carboxy group, an amino group and a carboxy group, an amino group and an isocyanate group, an epoxy group (glycidyl group) and an amino group, a hydroxyl group and an epoxy group, a hydroxyl group and an isocyanate group, etc. Among these combinations of the functional groups, the combination of a hydroxyl group and an isocyanate group is preferred in view of easy control of the reaction. Particularly, a suitable combination is a copolymer containing a hydroxyl group and the compound containing an isocyanate group.

Examples of the isocyanate compound having a polymerizable carbon double bond group include the above-described 2-(meth)acryloyloxyethyl isocyanate and alkylene oxide adducts thereof, etc.

From the viewpoint of improving adhesiveness and a stress relaxation property, the compound that includes a functional group capable of reacting with the functional groups and a polymerizable carbon double bond group is contained in an amount of preferably 10 parts by mass or less, more preferably 5 parts by mass or less, further preferably 1 part by mass or less, and particularly preferably 0.1 parts by mass or less relative to 100 parts by mass of the acrylic polymer (A). Note that a lower limit value is usually 0 parts by mass.

The acrylic polymer (A) has a hydroxyl value of preferably 30 mgKOH/g or more, more preferably 50 mgKOH/g or more, and particularly preferably 70 mgKOH/g or more. Furthermore, an upper limit of the hydroxyl value is generally 150 mgKOH/g, preferably 120 mgKOH/g. Note that the hydroxyl value can be obtained by determining an amount of a free hydroxyl group contained in 1 g of the acrylic polymer (A) from a compositional ratio of a monomer used in polymerization, and calculating an amount (unit: mg) of potassium hydroxide for neutralizing acetic acid necessary for acetylating the free hydroxyl group.

In view of suppressing increase in the storage shear modulus (G′) at low temperature, a glass transition temperature (Tg) of the acrylic polymer (A) is preferably −20° C. or lower, more preferably-23° C. or lower, further preferably −25° C. or lower, and particularly preferably −30° C. or lower. Note that due to concerns about a decreased storage shear modulus at high temperature causing paste overflow, etc., a lower limit value of the glass transition temperature (Tg) is usually −50° C.

In the present disclosure, the glass transition temperature (Tg) can be determined by measuring dynamic viscoelasticity using a dynamic viscoelasticity measurement device with a shearing mode at a frequency of 1 Hz, and reading a temperature at which a maximum loss tangent (tan δ) is observed.

For example, the acrylic polymer (A) is formed into a cylindrical object with a diameter of 8 mm (height: 1.0 mm), for which the loss tangent (tan δ) can be measured using a viscoelasticity measurement device (“DHR 2” manufactured by T. A. Instruments) under the following measurement conditions.

### (Measurement Conditions)

Measurement instrument: 8-mm-diameter parallel-plate
Strain: 0.1%
Frequency: 1 Hz
Measurement temperature: −50 to 80° C.
Temperature rise rate: 5° C./min

A weight-average molecular weight (Mw) of the acrylic polymer (A) is preferably 400,000 or more, more preferably 500,000 or more, and further preferably 550,000 or more because an adhesive composition with high cohesive force can be obtained.

Additionally, an upper limit value of the weight-average molecular weight (Mw) of the acrylic polymer (A) is preferably 1,500,000 or less, more preferably 1,200,000 or less, and further preferably 1,000,000 or less in view of handleability and uniform stirring performance.

In the present disclosure, the weight-average molecular weight (Mw) can be determined as follows, for example.

### (Measurement Method of Weight-Average Molecular Weight)

A measurement sample is prepared by dissolving 4 mg of the acrylic polymer (A) in 12 mL of tetrahydrofuran (THF), and a Gel Permeation Chromatography (GPC) analyzer (“HLC-8320GPC” manufactured by Tosoh Corporation) is used to measure a molecular weight distribution curve under the following conditions, thereby obtaining the weight-average molecular weight (Mw).
Guard column: TSKguardcolumnHXL
Separation column: TSKgelGMHXL (4 columns)
Temperature: 40° C.
Injection amount: 100 μL
In terms of polystyrene
Solvent: THF
Flow rate: 1.0 mL/min

The acrylic polymer (A) is contained in an amount of generally 10 to 75% by mass, preferably 12 to 73% by mass, more preferably 20 to 71% by mass, and particularly preferably 30 to 69% by mass relative to the amount of the adhesive composition.

Note that in the present disclosure, the adhesive composition includes the acrylic polymer (A) containing no carboxy group. Preferably, the adhesive composition does not include an acrylic polymer containing a carboxy group in view of adhesiveness, moisture resistance, and a corrosive effect on a base material.

### [Photoinitiator (B)]

The adhesive composition includes a photoinitiator (B).

The photoinitiator (B) is not particularly limited as long as it is a compound that generates radicals with active energy rays.

The photoinitiator (B) is broadly separated into two categories depending on a radical generation mechanism: a hydrogen abstraction-type photoinitiator (b1) that can form an excited complex of the excited initiator and a hydrogen donor in the system, and transfer the hydrogen of the hydrogen donor; and a cleavage-type photoinitiator (b2) that can generate radials through cleavage and decomposition of the single bond of the initiator itself.

The photoinitiator (B) may be either the hydrogen abstraction-type photoinitiator (b1) or the cleavage-type photoinitiator (b2). Each may be used alone, or both may be used in mixture. Furthermore, one kind or a combination of two or more kinds of each photoinitiator may be used.

Among them, in the present disclosure, the hydrogen abstraction-type photoinitiator (b1) is preferred because it does not require a functional group such as a polymerizable carbon double bond group for the acrylic polymer (A) itself, resulting in efficient crosslinking.

Examples of the hydrogen abstraction-type photoinitiator (b1) include benzophenone, 4-methyl benzophenone, 2,4,6-trimethyl benzophenone, 4-phenyl benzophenone, 3,3′-dimethyl-4-methoxy benzophenone, 4-(meth)acryloyloxy benzophenone, methyl 2-benzoylbenzoate, methyl benzoylformate, bis(2-phenyl-2-oxoacetic acid)oxybisethylene, 4-(1,3-acryloyl-1,4,7,10,13-pentaoxotridecyl)benzophenone, thioxanthone, 2-chlorothioxanthone, 3-methylthioxanthone, 2,4-dimethylthioxanthone, 2-methylanthraquinone, 2-ethylanthraquinone, 2-t-butylanthraquinone, 2-aminoanthraquinone, derivatives thereof, and the like. Among them, 4-methyl benzophenone and 2,4,6-trimethyl benzophenone are preferred.

Examples of the cleavage-type photoinitiator (b2) include 2,2-dimethoxy-1,2-diphenylethane-1-one, 1-hydroxycyclohexylphenyl ketone, 2-hydroxy-2-methyl-1-phenyl-propan-1-one, 1-(4-(2-hydroxyethoxy)phenyl)-2-hydroxy-2-methyl-1-propan-1-one, 2-hyrodoxy-1-[4-{4-(2-hydroxy-2-methyl-propionyl)benzyl} phenyl]-2-methyl-propan-1-one, oligo (2-hydroxy-2-methyl-1-(4-(1-methylvinyl)phenyl) propanone), methyl phenyl glyoxylate, 2-benzyl-2-dimethylamino-1-(4-morpholinophenyl) butan-1-one, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, bis(2,4,6-trimethylbenzoyl)-phenylphosphine oxide, 2,4,6-trimethylbenzoyldiphenylphosphine oxide, (2,4,6-trimethylbenzoyl)ethoxyphenylphosphine oxide, bis(2,6-dimethoxybenzoyl) 2,4,4-trimethylpenthylphosphine oxide, derivatives thereof, and the like.

The photoinitiator (B) is contained in an amount of generally 0.1 to 10 parts by mass, preferably 0.5 to 6 parts by mass, and particularly preferably 1 to 4 parts by mass relative to 100 parts by mass of the acrylic polymer (A). The amount equal to or more than the lower limit value tends to prevent poor curing, whereas the amount equal to or less than the upper limit value tends to easily prevent decrease in solution stability, such as precipitation from the adhesive composition, and easily prevent problems such as embrittlement and coloration.

### [Epoxy Compound (C)]

The adhesive composition includes an epoxy compound (C).

Commonly, as an additive (auxiliary adhesive agent) for improving adhesiveness of an adhesive sheet, a silane coupling agent is generally used. Even though a silane coupling agent has an excellent effect of improving adhesiveness to a glass member, it is insufficient as an auxiliary adhesive agent for a flexible member.

The present inventors have made an intensive investigation in view of the circumstance. Consequently, the present inventors have found that by using the epoxy compound (C), it is possible to provide an adhesive sheet excellent in adhesiveness to a flexible member, especially polyimide.

The epoxy compound (C) preferably has Hansen solubility parameters (δD, δP, δH) satisfying the following in view of adhesiveness to a flexible member.

That is, regarding the Hansen solubility parameters [HSP] (δD, δP, δH) of the epoxy compound (C), an HSP distance (Ra) between the Hansen solubility parameters of the epoxy compound (C) and Hansen solubility parameters of the acrylic polymer (A) is preferably 2.0 to 10.0. The HSP distance is more preferably 2.5 to 9.0, even more preferably 3.0 to 8.0.

When the HSP distance between the epoxy compound (C) and the acrylic polymer (A) is equal to or more than the lower limit value, appropriate bleed-out leads to improved adhesiveness to a flexible member as an adherend. When the HSP distance is equal to or less than the upper limit value, favorable compatibility can be obtained between the epoxy compound (C) and the acrylic polymer (A), and deterioration in transparency tends to be prevented.

Furthermore, in the Hansen solubility parameters (δD, δP, δH) of the epoxy compound (C), the polar term δP is preferably 4.5 MPa^{0.5} or more, further preferably 5.0 MPa^{0.5} or more. Additionally, the hydrogen bond term δH is preferably 4.0 MPa^{0.5} or more, further preferably 4.5 MPa^{0.5} or more.

The δP and δH of the epoxy compound (C) within the above ranges lead to good wetting of a highly-polar member sheet such as polyimide and thus improved adhesion.

The “Hansen solubility parameters [HSP]” herein refer to the measure of solubility, that is, how substances dissolve into one another.

The HSP are based on the solubility parameters introduced by Hildebrand, and divided into three components of a dispersion term δD, a polar term δP, and a hydrogen bond term δH, which are represented in a three-dimensional space. The dispersion term δD represents the effect of dispersion force. The polar term δP represents the effect of dipole-dipole force. The hydrogen bond term δH represents the effect of hydrogen bonding force. They can be respectively described as follows (each unit herein is MPa^{0.5}).
δD: energy from dispersion force between molecules
δP: energy from polar force between molecules
δH: energy from hydrogen bonding force between molecules

In the HSP, the dispersion term δD reflects van der Waals force, the polar term δP reflects dipole moment, and the hydrogen bond term δH reflects actions of water, alcohol, etc. Those having similar HSP vectors to each other can be determined as highly soluble, and the similarity of the vectors can be determined by the distance of Hansen solubility parameters (HSP distance). Additionally, the Hansen solubility parameters can be the measure not only for determining the solubility, but also for determining how easy it is for one substance to be present in another substance, that is, how good the dispersion is.

In the present disclosure, HSP (δD, δP, δH) can be easily computed based on its chemical structure by using, for example, computer software, Hansen Solubility Parameters in Practice (HSPiP).

Specifically, HSP can be obtained from the chemical structure by a Y-MB method implemented in HSPIP. When the chemical structure is unknown, HSP can be determined by a sphere technique implemented in HSPIP based on results of a dissolution test using a plurality of solvents.

The HSP distance (Ra) can be calculated, for example by the following expression, wherein HSP of the acrylic polymer (A) is (δD₁, δP₁, δH₁) and HSP of the epoxy compound (C) is (δD₂, δP₂, δH₂).

$$HSP distance ( Ra ) = {\{ 4 \times {( δ {D}_{1} - δ {D}_{2} )}^{2} + {( δ {P}_{1} - δ {P}_{2} )}^{2} + {( δ {H}_{1} - δ {H}_{2} )}^{2} \}}^{0.5}$$

Note that the definition and calculation of HSP are described in the following document.

### Charles M. Hansen, Hansen Solubility Parameters: A Users Handbook (CRC Press, 2007).

In the present disclosure, examples of the epoxy compound (C) include monofunctional epoxy and polyfunctional epoxy compounds. In view of adhesiveness, a polyfunctional epoxy compound is preferred.

The polyfunctional epoxy compound is not particularly limited as long as it contains two or more epoxy groups in one molecule, and may be in a solid or liquid state. The use of the polyfunctional epoxy compound can provide an adhesive sheet with excellent adhesiveness to a flexible member, particularly polyimide.

It is considered that the effect of improving adhesion to a flexible member in the present disclosure is exhibited through the following mechanism.

The epoxy group contained in the epoxy compound (C) can produce interaction with a functional group on a flexible member as an adherend (for example, a maleimide group or an amide group in a case of polyimide, an ester group in a case of polyester) through an irreversible covalent bond, hydrogen bond, or the like. Furthermore, in the case of the polyfunctional epoxy compound, it can produce interaction or a covalent bond such as a hydrogen bond with a functional group such as a hydroxyl group contained in the acrylic polymer (A) or a crosslinking agent, and even in a case of a monofunctional epoxy compound, the chain of the epoxy compound can produce interaction with the chain of the acrylic polymer. It is believed that the epoxy compound (C) interacts with not only the constituent component of the adhesive composition but also an interface with a flexible member in this manner, thereby improving adhesion to the flexible member, particularly polyimide.

Furthermore, it has been found in the present disclosure that the epoxy compound (C) has appropriate compatibility with the adhesive composition, and thus causes segregation of a part of the epoxy group on a surface of an adhesive sheet to produce a bond or interaction even with a functional group on a flexible member.

Examples of the epoxy compound (C) include: aromatic epoxy compounds, including aromatic monofunctional epoxy compounds such as phenyl glycidyl ether, 2-phenylphenol glycidyl ether, o-cresyl glycidyl ether, and butylphenyl glycidyl ether, and aromatic polyfunctional epoxy compounds such as bisphenol-A epoxy compound, bisphenol-F epoxy compound, naphthalene epoxy compound, biphenyl epoxy compound, resorcinol epoxy compound, phenol novolac epoxy compound, and cresol novolac epoxy compound; aliphatic epoxy compounds, including aliphatic monofunctional epoxy compounds such as butyl glycidyl ether, 2-ethylhexyl glycidyl ether, 1,2-epoxytetradecane, lauryl glycidyl ether, lauryl alcohol (ethylene oxide) glycidyl ether, and higher alcohol glycidyl ether, and aliphatic polyfunctional epoxy compounds such as ethylene glycol diglycidyl ether, diethylene glycol diglycidyl ether, polyethylene glycol diglycidyl ether, propylene glycol diglycidyl ether, dipropylene glycol diglycidyl ether, tripropylene glycol diglycidyl ether, (poly) propylene glycol diglycidyl ether, butanediol diglycidyl ether, poly tetramethylene glycol diglycidyl ether, neopentyl glycol diglycidyl ether, 1,6-hexanediol diglycidyl ether, trimethylolpropane diglycidyl ether, trimethylolpropane triglycidyl ether, glycerol diglycidyl ether, glycerol triglycidyl ether, diglycerol polyglycidyl ether, polyglycerol polyglycidyl ether, sorbitol polyglycidyl ether, cyclohexane diglycidyl ether, dicyclopentadiene diglycidyl ether, hydrogenated bisphenol A diglycidyl ether, hydrogenated bisphenol F diglycidyl ether, hexahydrophthalic acid diglycidyl ester, vinyl(3,4-cyclohexene) dioxide, 2-(3,4-epoxycyclohexyl)-5,1-spiro-(3,4-epoxycyclohexyl)-m-dioxane, and epoxidized polybutadiene; heterocyclic epoxy compounds, including heterocyclic monofunctional epoxy compounds such as N-glycidylphthalimide, and heterocyclic polyfunctional epoxy compounds such as triglycidyl isocyanurate; halogenated epoxy compounds, glycidyl amine epoxy compounds, epoxy group-containing rubber compounds, epoxy group-containing polyurethane compounds, epoxy group-containing acrylic compounds, and the like. These may be used alone or in combination of two or more.

Among them, from the viewpoint of enhancing adhesion to an adherend, polyfunctional epoxy compounds are preferred, and bifunctional epoxy compounds are more preferred.

Furthermore, from the viewpoint of maintaining appropriate compatibility with the adhesive composition and softness of an adhesive sheet, aliphatic epoxy compounds are preferred, among which a compound having an alkylene glycol backbone is preferred from the viewpoint of its appropriate compatibility. In particular, polyalkylene glycol diglycidyl ether is preferred, and polyethylene glycol diglycidyl ether is further preferred.

When the epoxy compound (C) has an alkylene glycol backbone, the number of repeating units thereof is preferably 2 to 30, more preferably 3 to 25, further preferably 4 to 20, and particularly preferably 6 to 15.

Furthermore, the epoxy compound (C) is preferably an epoxy compound having a linear alkylene glycol backbone in view of adhesiveness.

The epoxy compound (C) is preferably an epoxy compound having an epoxy equivalent weight of 80 to 500 in view of adhesiveness, where the epoxy equivalent weight is more preferably 100 to 450, further preferably 120 to 400, and particularly preferably 200 to 400.

Additionally the epoxy compound (C) has a weight-average molecular weight of preferably 200 to 1000, more preferably 250 to 900, and particularly preferably 300 to 800 in view of adhesiveness.

The epoxy compound (C) is contained in an amount of generally 0.01 to 10 parts by mass, preferably 0.03 to 5 parts by mass, more preferably 0.05 to 3 parts by mass, particularly preferably 0.07 to 1 parts by mass, and especially preferably 0.1 to 0.7 parts by mass relative to 100 parts by mass of the acrylic polymer (A). When the amount is equal to or more than the lower limit value, an adhesive force to an adherend tends to be improved. When the amount is equal to or less than the upper limit value, it is easy to keep softness of an adhesive sheet, and an adhesive sheet excellent in flexibility tends to be obtained.

### [Radically Polymerizable Compound (D)]

In addition to the acrylic polymer (A), the photoinitiator (B), and the polyfunctional epoxy compound (C), the adhesive composition preferably further includes a radically polymerizable compound (D) in view of excellent adhesion to a flexible member.

The radically polymerizable compound (D) preferably has an alkylene glycol backbone in view of flexibility.

Additionally, in view of flexibility, the radically polymerizable compound (D) preferably has a urethane bond.

As the alkylene glycol backbone, preferred from the viewpoint of decreasing the storage shear modulus at low temperature is an alkylene glycol backbone including an alkylene chain having 2 to 10 carbon atoms, further 2 to 8 carbon atoms, particularly 2 to 6 carbon atoms, and especially 2 to 4 carbons atoms. In particular, an ethylene glycol backbone, a propylene glycol backbone, a butylene glycol backbone, and the like are preferred, among which the propylene glycol backbone is more preferred.

An example of the radically polymerizable compound having the alkylene glycol backbone is a monofunctional (meth)acrylic oligomer represented by the following general formula (1),

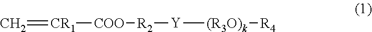

wherein R₁ represents a hydrogen or a methyl group; R₂ and R₄ independently represent an alkyl group having 1 to 20 carbon atoms or an alkenyl group having 2 to 20 carbon atoms, and optionally have an ether bond or a cyclic structure in their chain; Y represents any linking group selected from a urethane bond, an ester bond, an ether bond, a carbonate bond, an amide bond, and a urea bond; R₃ represents an alkylene group, which is an ethylene group or a propylene group; “k” represents a positive number of 1 to 500, which indicates r+s as a total number of repeating units (C₂H₄O)ᵣ and (C₃H₆O)ₛ. In a case that an oxyethylene structure and an oxypropylene structure coexist, the monofunctional (meth)acrylic oligomer may be in a random or block form.

The positive number “k” in the general formula (1) is preferably 10 to 500, more preferably 100 to 450, and further preferably 200 to 400 from the viewpoint of maintaining high recovering ability at the time of bending while decreasing the storage shear modulus at low temperature.

Above all, the radically polymerizable compound having the alkylene glycol backbone is preferably a monofunctional urethane (meth)acrylate having a urethane bond due to its excellent flexibility.

Since the monofunctional urethane (meth)acrylate has high polarity and long chain length, high recovering ability tends to be obtained due to polymer chain entanglement. Additionally, due to the oxypropylene structure thereof with high molecular rotation, a low storage shear modulus tends to be obtained, which makes the monofunctional urethane (meth)acrylate particularly effective.

When homopolymerization is carried out in the radically polymerizable compound having the alkylene glycol backbone, that is, only the radically polymerizable compound is polymerized to produce a polymer, a glass transition temperature of the polymer is preferably-40° C. or lower, more preferably −45° C. or lower, and further preferably-50° C. or lower from the viewpoint of maintaining high recovering ability at the time of bending while decreasing a storage shear modulus at low temperature.

In the radically polymerizable compound having the alkylene glycol backbone, because of concerns about paste overflow due to decrease in a storage shear modulus at high temperature, etc., the glass transition temperature of the polymer obtained by homopolymerization is preferably −80° C. or higher, more preferably-75° C. or higher, and further preferably −70° C. or higher.

The radically polymerizable compound having the alkylene glycol backbone has a weight-average molecular weight (Mw) of preferably 30,000 or less, more preferably 28,000 or less, and further preferably 25,000 or less from the viewpoint of maintaining high recovering ability at the time of bending while decreasing the storage shear modulus at low temperature.

Furthermore, a lower limit value of the weight-average molecular weight (Mw) of the radically polymerizable compound having the alkylene glycol backbone is preferably 3,000 or more, more preferably 4,000 or more, and even more preferably 5,000 or more from the viewpoint of maintaining high recovering ability at the time of bending while preventing bleed-out from decreasing the adhesiveness.

Note that the weight-average molecular weight (Mw) of the radically polymerizable compound having the alkylene glycol backbone can be determined according to the “Measurement Method of Weight-Average Molecular Weight” as described with regard to the acrylic polymer (A).

Furthermore, as the radically polymerizable compound (D), besides the radically polymerizable compound having the alkylene glycol backbone, for example, a monofunctional (meth)acrylic monomer, a polyfunctional (meth)acrylic monomer, a polyfunctional (meth)acrylic oligomer, etc., are also usable. One kind or a combination of two or more kinds thereof can be used.

### [Monofunctional (Meth)acrylic Monomer]

From the monofunctional (meth)acrylic monomer, the radically polymerizable compound having the alkylene glycol backbone is excluded. Examples of the monofunctional (meth)acrylic monomer include linear or branched alkyl (meth)acrylates.

Specific examples thereof include n-butyl (meth)acrylate, isobutyl (meth)acrylate, sec-butyl (meth)acrylate, t-butyl (meth)acrylate, pentyl (meth)acrylate, isopentyl (meth)acrylate, neopentyl (meth)acrylate, hexyl (meth)acrylate, cyclohexyl (meth)acrylate, heptyl (meth)acrylate, 2-ethylhexyl (meth)acrylate, n-octyl (meth)acrylate, isooctyl (meth)acrylate, nonyl (meth)acrylate, isononyl (meth)acrylate, t-butylcyclohexyl (meth)acrylate, decyl (meth)acrylate, isodecyl (meth)acrylate, undecyl (meth)acrylate, lauryl (meth)acrylate, tridecyl (meth)acrylate, tetradecyl (meth)acrylate, cetyl (meth)acrylate, stearyl (meth)acrylate, isostearyl (meth)acrylate, isobornyl (meth)acrylate, 3,5,5-trimethylcyclohexane (meth)acrylate, dicyclopentanyl (meth)acrylate, dicyclopentenyl (meth)acrylate, dicyclopentenyloxyethyl (meth)acrylate, and the like.

### [Polyfunctional (Meth)acrylic Monomer]

From the polyfunctional (meth)acrylic monomer, the radically polymerizable compound having the alkylene glycol backbone is excluded. Examples of the polyfunctional (meth)acrylic monomer include 1,4-butanediol di(meth)acrylate, glycerol di(meth)acrylate, neopentyl glycol di(meth)acrylate, glycerol glycidyl ether di(meth)acrylate, tricyclodecane dimethacrylate, tricyclodecane dimethanol di(meth)acrylate, bisphenol A polyethoxy di(meth)acrylate, bisphenol A polypropoxy di(meth)acrylate, bisphenol F polyethoxy di(meth)acrylate, ethylene glycol di(meth)acrylate, trimethylolpropane trioxyethyl (meth)acrylate, ε-caprolactone-modified tris(2-hydroxyethyl)isocyanurate tri(meth)acrylate, pentaerythritol tri(meth)acrylate, propoxylated pentaerythritol tri(meth)acrylate, ethoxylated pentaerythritol tri(meth)acrylate, pentaerythritol tetra(meth)acrylate, propoxylated pentaerythritol tetra(meth)acrylate, ethoxylated pentaerythritol tetra(meth)acrylate, dipentaerythritol hexa(meth)acrylate, polyethylene glycol di(meth)acrylate, polypropylene glycol di(meth)acrylate, polytetramethylene glycol di(meth)acrylate, tris(acryloxyethyl)isocyanurate, dipentaerythritol penta(meth)acrylate, tripentaerythritol hexa(meth)acrylate, tripentaerythritol penta(meth)acrylate, hydroxypivalic acid neopentyl glycol di(meth)acrylate, di(meth)acrylate of ε-caprolactone adduct of hydroxypivalic acid neopentyl glycol, trimethylolpropane tri(meth)acrylate, trimethylolpropane polyethoxy tri(meth)acrylate, ditrimethylolpropane tetra(meth)acrylate, and the like.

### [Polyfunctional (Meth)acrylic Oligomer]

From the polyfunctional (meth)acrylic oligomer, the radically polymerizable compound having the alkylene glycol backbone is excluded. Examples of the polyfunctional (meth)acrylic oligomer include polyfunctional (meth)acrylic oligomers such as polyfunctional polyester (meth)acrylate oligomer, polyfunctional epoxy (meth)acrylate oligomer, polyfunctional urethane (meth)acrylate oligomer, and polyfunctional polyether (meth)acrylate oligomer.

The radically polymerizable compound (D) is contained in an amount of generally 10 to 100 parts by mass, preferably 20 to 90 parts by mass, and particularly preferably 40 to 80 parts by mass relative to 100 parts by mass of the acrylic polymer (A). When the amount of the radically polymerizable compound (D) is within the above range, an adhesive sheet excellent in flexibility tends to be obtained.

### [Thermal Crosslinking Agent]

The adhesive composition may include a thermal crosslinking agent in view of enhancing cross-link density and improving long-term reliability.

Examples of the thermal crosslinking agent include isocyanate crosslinking agents, aziridine crosslinking agents, melamine crosslinking agents, aldehyde crosslinking agents, amine crosslinking agents, and metal chelate crosslinking agents. Among them, isocyanate crosslinking agents are preferred for use due to their excellent reactivity with the acrylic polymer (A).

The thermal crosslinking agent is contained in an amount of generally 5 to 40 parts by mass, preferably 10 to 30 parts by mass, relative to 100 parts by mass of the acrylic polymer (A).

Note that when the polyfunctional (meth)acrylic monomer and the polyfunctional (meth)acrylic oligomer described with regard to the radically polymerizable compound (D) are used, they also function as a crosslinking agent.

When the polyfunctional (meth)acrylic monomer or polyfunctional (meth)acrylic oligomer is used as the crosslinking agent, the amount thereof is generally 10 to 100 parts by mass, preferably 20 to 90 parts by mass, and particularly preferably 40 to 80 parts by mass relative to 100 parts by mass of the acrylic polymer (A). When the amount of the polyfunctional (meth)acrylic monomer or polyfunctional (meth)acrylic oligomer is within the above range, an adhesive sheet excellent in flexibility tends to be obtained.

### [Other Components]

The adhesive composition can appropriately contain various additives as “other components,” for example, an ultraviolet absorber, a corrosion inhibitor, a silane coupling agent, a tackifier resin, an antioxidant, a light stabilizer, a metal deactivator, an oxidization inhibitor, a moisture absorbent, and inorganic particles, as necessary to the extent that the effects of the present disclosure are not impaired.

Additionally, if necessary, a reaction catalyst such as a tertiary amine compound, a quaternary ammonium compound, and a tin laurate compound may be contained as appropriate.

These can be used alone or in combination of two or more.

### (Ultraviolet Absorber)

Examples of the ultraviolet absorber include a benzophenone ultraviolet absorber, a benzotriazole ultraviolet absorber, a triazine ultraviolet absorber, a salicylic acid ultraviolet absorber, a cyano acrylate ultraviolet absorber, a benzoxazine ultraviolet absorber, and the like. One kind or a combination of two or more kinds of these ultraviolet absorbers can be used.

The ultraviolet absorber (if used) is contained in an amount of preferably 0.01 to 20 parts by mass, particularly preferably 0.1 to 15 parts by mass, and further preferably 0.5 to 10 parts by mass relative to 100 parts by mass of the acrylic polymer (A). When the amount is equal to or more than the lower limit value, light resistance reliability tends to be improved. When the amount is equal to or less than the upper limit value, yellowing resistance tends to be improved.

### (Corrosion Inhibitor)

As the corrosion inhibitor, for example, triazoles, benzotriazoles, etc., are preferred, which can prevent an optical member from corroding. These can be used alone or in combination of two or more.

The corrosion inhibitor (if used) is contained in an amount of preferably 0.01 to 5 parts by mass, particularly preferably 0.1 to 3 parts by mass, relative to 100 parts by mass of the acrylic polymer (A).

The other components are contained in an amount of preferably 5 parts by mass or less, particularly preferably 1 part by mass or less, and further preferably 0.5 parts by mass or less relative to 100 parts by mass of the acrylic polymer (A). When the amount is too large, compatibility with the acrylic polymer tends to decrease, resulting in reduced durability.

The adhesive composition is prepared by mixing predetermined amounts of the acrylic polymer (A), the photoinitiator (B), the epoxy compound (C), and the radically polymerizable compound (D), as well as the thermal crosslinking agent and the other components as necessary.

### <Method for Producing Present Adhesive Sheet>

Next, a method for producing the present adhesive sheet will be described.

However, the following description is merely an example of the method for producing the present adhesive sheet, and the present adhesive sheet is not limited to the one produced by the production method.

The present adhesive sheet may be produced by: preparing the adhesive composition for forming the present adhesive sheet, the adhesive composition including the acrylic polymer (A), the photoinitiator (B), the epoxy compound (C), preferably the radically polymerizable compound (D), and the thermal crosslinking agent and the other components as necessary; forming the adhesive composition into a sheet; curing the same by crosslinking, i.e., polymerization reaction; and processing the resultant as appropriate and as necessary.

Moreover, the present adhesive sheet may be formed by: preparing the adhesive composition for forming the present adhesive sheet in the same manner as described above; coating a member sheet or a constituent member of a flexible image display device with the adhesive composition; and curing the adhesive composition.

However, the method is not limited thereto.

Upon preparing the adhesive composition for forming the present adhesive sheet, the raw materials may be kneaded using a temperature-controllable kneader (for example, a single-screw extruder, a twin-screw extruder, a planetary mixer, a twin-screw mixier, a pressure kneader, etc.).

Note that upon kneading various raw materials, various additives such as an antioxidant may be blended with the resin in advance and then fed to the kneader, or all the materials may be melt-mixed in advance and then supplied, or only the additives may be condensed into the resin in advance to prepare a master batch, and then supplied.

As the method for forming the adhesive composition into a sheet, a known method, for example, wet lamination, dry lamination, extrusion casting using a T-die, extrusion lamination, calendaring process, an inflation method, injection molding, liquid-injection curing, etc., can be employed. Among them, wet lamination, extrusion casting, and extrusion lamination are suitable for producing a sheet.

Furthermore, the adhesive composition can be cured by irradiation with active energy rays. The present adhesive sheet can be produced by irradiating the molded adhesive composition, for example, the adhesive composition formed into a sheet, with active energy rays. Note that besides the irradiation with active energy rays, heating can also be performed for further curing.

Furthermore, irradiation energy, irradiation time, irradiation method, etc. with active energy rays are not particularly limited as long as the photoinitiator (B) can be activated to polymerize the monomer component.

When the hydrogen abstraction-type photoinitiator (b1) is used as the photoinitiator (B), a hydrogen abstraction reaction occurs also in the acrylic polymer (A) to incorporate the acrylic polymer (A) into a crosslinked structure, thereby forming a crosslinked structure having many crosslinking points.

Accordingly, the present adhesive sheet is preferably obtained by curing using the hydrogen abstraction-type photoinitiator (b1).

Examples of the active energy rays for the irradiation include: rays such as far-ultraviolet rays, ultraviolet rays, near-ultraviolet rays, infrared rays, and visible rays; and ionization radiation such as X-ray, α-ray, β-ray, γ-ray, electron beam, proton beam, and neutron beam. Among them, from the viewpoints of preventing damage to a constituent member of an optical device and controlling reaction, an ultraviolet ray is suitable. Moreover, in view of curing speed, availability of an irradiation device, cost, etc., curing with ultraviolet radiation is advantageous.

As a light source for the ultraviolet radiation, a high-pressure mercury lamp, an ultra-high-pressure mercury lamp, a low-pressure mercury lamp, a carbon arc lamp, a metal halide lamp, a xenon lamp, a chemical lamp, an electrodeless discharge lamp, an LED, and the like can be used, which emit light in a wavelength range of 150 to 450 nm. Among them, a high-pressure mercury lamp is preferably used.

An exposure dose (integrated light intensity) of the active energy ray is preferably 0.03 to 3 J/cm², more preferably 0.1 to 2 J/cm², and further preferably 0.3 to 1.5 J/cm² from the viewpoint of curing.

Furthermore, as another implementation of the method for producing the present adhesive sheet, the adhesive composition can be dissolved in an appropriate solvent and coated by various coating techniques.

In the case of using the coating technique, the present adhesive sheet can also be obtained by thermal curing, besides the curing by the irradiation with active energy rays. In the case of the coating, the thickness of the present adhesive sheet can be controlled by coating thickness and solids concentration of a coating liquid.

For example, the present adhesive sheet can be formed by dissolving the adhesive composition in a solvent, thereafter coating a release film with the adhesive composition, drying, and curing the resultant by the irradiation with active energy rays. The release film may further be laminated as necessary. In this case, the release film may be laminated on the release film that is coated with the adhesive composition and dried, followed by curing by the irradiation with active energy rays; or after the release film is coated with the adhesive composition and dried, the release film may be laminated thereon, followed by curing by the irradiation with active energy rays to form the present adhesive sheet.

The solvent is not particularly limited as long as it can dissolve the adhesive composition. Examples thereof include: ester solvents such as methyl acetate, ethyl acetate, butyl acetate, methyl acetoacetate, and ethyl acetoacetate; ketone solvents such as acetone, methyl ethyl ketone, and methyl isobutyl ketone; aromatic solvents such as toluene and xylene; and alcohol solvents such as methanol, ethanol, and propylene alcohol. One kind or a combination of two or more kinds thereof can be used. Among them, in view of solubility, a drying property, a cost, etc., ethyl acetate, acetone, methyl ethyl ketone, and toluene are preferred. In particular, ethyl acetate is suitably used.

In view of a drying property, the solvent is contained in an amount of preferably 600 parts by mass or less, more preferably 500 parts by mass or less, further preferably 400 parts by mass or less, and particularly preferably 300 parts by mass or less relative to 100 parts by mass of the acrylic polymer (A). On the other hand, the amount is preferably 1 part by mass or more, more preferably 50 parts by mass or more, further preferably 100 parts by mass or more, and particularly preferably 150 parts by mass or more.

The coating method can be performed in a common manner, for example, by roll coating, die coating, gravure coating, comma coating, screen printing, or bar coating.

After the drying, the solvent content of the adhesive composition is preferably 1% by mass or less, more preferably 0.5% by mass or less, particularly preferably 0.1% by mass or less, and the most preferably 0% by mass.

A drying temperature is generally 40 to 150° C., more preferably 45 to 140° C., even more preferably 50 to 130° C., and particularly preferably 55 to 120° C. The temperature within the above range makes it possible to prevent thermal deformation of the release film while efficiently and relatively safely removing the solvent.

A drying time is generally 1 to 30 minutes, more preferably 3 to 25 minutes, and further preferably 5 to 20 minutes. The time within the above range makes it possible to efficiently and sufficiently remove the solvent.

Examples of the drying method include drying with a dryer or a heat roll, drying by blowing hot air on a film, etc. Among them, the use of a dryer is preferred since it enables uniform and easy drying. One kind or a combination of two or more kinds thereof can be used.

### (Thickness)

A thickness of the present adhesive sheet is not particularly limited. The thickness of 10 μm or more leads to favorable handleability, whereas the thickness of 1000 μm or less contributes to thinning the present adhesive sheet.

Accordingly, the thickness of the present adhesive sheet is preferably 10 μm or more. Above all, the more preferable thickness is 15 μm or more, particularly 20 μm or more, and further 25 μm or more.

On the other hand, an upper limit thereof is preferably 1000 μm or less. Above all, the more preferable thickness is 500 μm or less, particularly 250 μm or less, further 100 μm or less, and especially 75 μm or less.

It is also possible to provide the release film on at least one side of the adhesive sheet obtained as described above, from the viewpoints of preventing blocking and preventing foreign matter adhesion.

That is, it is also possible to provide the present adhesive sheet as an adhesive sheet with a release film (adhesive sheet laminate) having a configuration in which a release film is laminated on one or both sides of an adhesive layer (the present adhesive sheet) composed of the adhesive composition.

In a case of providing the release film on both sides of the present adhesive sheet, a preferable laminate configuration includes a light-release film with relatively low release force and a heavy-release film with relatively high release force, the light-release film and the heavy-release film being laminated together.

In a case of using the adhesive sheet with a release film provided on both sides of the adhesive sheet, firstly, one release film (light-release film) may be peeled off to expose the one side of the adhesive sheet, onto which a member sheet or a constituent member of a flexible image display device (namely a first member) may be attached, and the other release film (heavy-release film) may be peeled off to expose the other side of the adhesive sheet, onto which a member sheet or a constituent member of a flexible image display device (namely a second member) may be attached.

As the release film, a known release film can be used as appropriate.

Regarding a material for the release film, for example, a film, such as a polyester film, a polyolefin film, a polycarbonate film, a polystyrene film, an acrylic film, a triacetyl cellulose film, and a fluororesin film, which is treated with a mold release agent such as a silicone resin, a release paper, etc. can be appropriately selected for use.

Among them, a polyester film, furthermore a polyethylene terephthalate (PET) film, and particularly a biaxially oriented PET film are preferred because of their excellent transparency, mechanical strength, heat resistance, softness, etc. A release film including a release layer provided on the base material can be used, where the release layer is obtained by curing a curable silicone mold release agent containing a silicone resin as a main component.

In general, when an adhesive sheet excellent in flexibility is used as the adhesive sheet with a release film, high release force of the release film tends to cause deformation of the adhesive sheet due to its softness upon peeling off the release film, and easily leave a peeling mark.

Accordingly, a release film, particularly a light-release film to be used for an adhesive sheet excellent in flexibility is preferably a release film that can be peeled off with even less force than a light-release type release film conventionally used for general purposes.

However, if a thickness of a layer of a mold release agent is increased to make the release film releasable with light force, a component derived from the layer of the mold release agent may transfer to the surface of the adhesive sheet and impair reliability of the adhesive sheet depending on the type of the mold release agent to be used. Therefore, the release film preferably has favorable releasability from the adhesive sheet and causes less migration of the mold release agent to the adhesive sheet.

The release force of the release film against the present adhesive sheet is preferably 1.5 to 0.05 N/cm, more preferably 1.2 to 0.06 N/cm, and further preferably 1.0 to 0.07 N/cm. The release force of the release film against the adhesive sheet is a measurement value obtained by a 180° peel test with a test speed of 300 m/min. The release force within the above range enables prevention of a peeling mark when the release film is peeled off from the present adhesive sheet.

Furthermore, a peak intensity of silicon atoms on an adhesive surface exposed by peeling off the release film from the present adhesive sheet is preferably 100 cps or less as measured by using an X-ray fluorescence spectrometer. The peak intensity of 100 cps or less is preferable because the reliability of the adhesive sheet used as a laminate for configuring an image display device is not impaired by the mold release agent transferred to the surface of the adhesive sheet. From this viewpoint, the peak intensity is more preferably 90 cps or less, further preferably 80 cps or less, and especially preferably 70 cps or less. Note that a lower limit is generally 0 cps.

A thickness of the release film is not particularly limited. Above all, for example, from the viewpoints of workability and handleability, the thickness is preferably 10 to 250 μm, more preferably 25 to 200 μm, and further preferably 35 to 190 μm.

Additionally, embossing or various processes of creating protrusions and recesses (such as a cone or pyramid shape, or a hemispherical shape) may be performed as necessary. Moreover, for the purpose of improving an adhesive property to various member sheets, various types of surface treatment, such as corona treatment, plasma treatment, and primer treatment, may be performed on the surface.

The present adhesive sheet may be a single-layer sheet consisting only of an acrylic adhesive layer formed from the adhesive composition, or a multilayer sheet in which a plurality of layers including an acrylic adhesive layer and other adhesive layers is laminated.

### <Physical Properties of Present Adhesive Sheets 1 and 2>

The present adhesive sheets 1 and 2 can have the following physical properties.

### (Storage Shear Modulus)

In the present adhesive sheet, a storage shear modulus at 25° C. (G′(25° C.)) obtained by dynamic viscoelasticity measurement with a shearing mode at a frequency of 1 Hz is 60 kPa or less. When the storage shear modulus at 25° C. (G′(25° C.)) is 60 kPa or less, it is possible to reduce interlayer stress at the time of bending a laminate or a laminate for an image display device, which is formed, for example, by attaching the present adhesive sheet to a member sheet, and prevent delamination and breakage of the member sheet or the constituent member of a flexible image display device.

From this viewpoint, the storage shear modulus at 25° C. (G′(25° C.)) is preferably 55 kPa or less, more preferably 50 kPa or less, and particularly preferably 45 kPa or less.

Note that a lower limit value of the storage shear modulus (G′(25° C.)) of the present adhesive sheet is preferably 5 kPa or more from the viewpoints of preventing paste overflow and keeping the shape of the adhesive sheet.

In the present adhesive sheet, a storage shear modulus at −20° C. (G′(−20° C.)) obtained by dynamic viscoelasticity measurement with a shearing mode at a frequency of 1 Hz is generally 1000 kPa or less, preferably 400 kPa or less, particularly preferably 300 kPa or less, and even more preferably 250 kPa or less.

Note that a lower limit value of the storage shear modulus (G′(−20° C.)) of the present adhesive sheet is preferably 50 kPa or more in view of the balance with a storage shear modulus at high temperature.

When the storage shear modulus (G′(−20° C.)) of the present adhesive sheet is within the above range, it is possible to reduce interlayer stress at the time of bending a laminate or a laminate for an image display device, which is formed, for example, by bonding the present adhesive sheet to a member sheet, particularly in a range from low to high temperature, such that delamination and breakage of the member sheet or the constituent member of a flexible image display device tend to be prevented.

In the present adhesive sheet, a storage shear modulus at −30° C. (G′(−30° C.)) obtained by dynamic viscoelasticity measurement with a shearing mode at a frequency of 1 Hz is preferably 1200 kPa or less, more preferably 1000 kPa or less, even more preferably 800 kPa or less, particularly preferably 700 kPa or less, and further preferably 500 kPa or less.

Note that a lower limit value of the storage shear modulus (G′(−30° C.)) of the present adhesive sheet is preferably 100 kPa or more in view of the balance with the storage shear modulus at high temperature.

When the storage shear modulus (G′(−30° C.)) of the present adhesive sheet is within the above range, it is possible to reduce interlayer stress at the time of bending a laminate or a laminate for an image display device, which is formed, for example, by bonding the present adhesive sheet to a member sheet, particularly in a range from low to high temperature, such that delamination and breakage of the member sheet or the constituent member of a flexible image display device tend to be prevented.

In the present adhesive sheet, a storage shear modulus at 60° C. (G′(60° C.)) obtained by dynamic viscoelasticity measurement with a shearing mode at a frequency of 1 Hz is generally 50 kPa or less, preferably 40 kPa or less, particularly preferably 35 kPa or less, and even more preferably 30 kPa or less from the viewpoint of achieving high adhesiveness.

Note that a lower limit value of the storage shear modulus (G′(60° C.)) of the present adhesive sheet is preferably 1 kPa or more from the viewpoints of preventing paste overflow and keeping the shape of the adhesive sheet.

In the present adhesive sheet, a storage shear modulus at 80° C. (G′(80° C.)) obtained by dynamic viscoelasticity measurement with a shearing mode at a frequency of 1 Hz is generally 30 kPa or less, preferably 25 kPa or less, particularly preferably 20 kPa or less, and even more preferably 15 kPa or less from the viewpoint of achieving high adhesiveness.

Note that a lower limit value of the storage shear modulus (G′(80° C.)) of the present adhesive sheet is preferably 1 kPa or more from the viewpoints of preventing paste overflow and keeping the shape of the adhesive sheet.

### (Loss Tangent (tan δ))

In the present adhesive sheet, a loss tangent (tan δ) at 25 to 60° C. obtained by dynamic viscoelasticity measurement with a shearing mode at a frequency of 1 Hz is generally 0.18 or more, preferably 0.20 or more, and particularly preferably 0.25 or more. An upper limit value is generally 1. When the loss tangent (tan δ) at 25 to 60° C. is equal to or more than the above numerical value, excellent flexibility tends to be achieved.

### (Maximum Point of Loss Tangent (tan δ) and Glass Transition Temperature (Tg))

In the present adhesive sheet, the loss tangent (tan δ) obtained by dynamic viscoelasticity measurement with a shearing mode at a frequency of 1 Hz has a maximum point at preferably −20° C. or lower, further preferably −25° C. or lower, particularly preferably −30° C. or lower, and even more preferably −35° C. or lower. A lower limit value is generally −80° C.

The maximum point of the loss tangent (tan δ) can be interpreted as a glass transition temperature (Tg). When the glass transition temperature (Tg) is within the above range, the storage shear modulus (G′(−20° C.)) of the present adhesive sheet can be easily adjusted to 1000 kPa or less.

When only one inflection point of the loss tangent (tan δ) obtained by dynamic viscoelasticity measurement with a shearing mode at a frequency of 1 Hz is observed, in other words, when the tan δ curve has a single-peak shape, the glass transition temperature (Tg) can be considered to be single.

The “maximum point” of the loss tangent (tan δ) means a peak value in the tan δ curve, namely, a point having the maximum value among inflection points where a differentiated value changes from positive (+) to negative (−) in a predetermined range or in an entire range.

The storage shear modulus G′ and the loss tangent (tan δ) at various temperatures can be measured by using a rheometer.

The storage shear modulus (G′) and the loss tangent (tan δ) can be adjusted to the above ranges by adjusting the kinds, weight-average molecular weights, etc., of the components (for example, the acrylic polymer (A), the radically polymerizable compound (D), etc.) contained in the adhesive composition that constitutes the present adhesive sheet, and further adjusting the gel fraction, etc., of the adhesive sheet. However, the method is not limited thereto.

### (Adhesion)

In the present adhesive sheet, adhesion to polyimide at 23° C. (P(23° C.)) is preferably 3.5 N/cm or more, while adhesion to polyimide at 60° C. (P(60° C.)) is preferably 1.5 N/cm or more. The adhesive sheet satisfying the above range has excellent adhesiveness in a wide temperature range, hardly suffers delamination even by bending a laminate bonded to an adherend such as a constituent member of an image display device, and thus tends to have excellent durability.

From this viewpoint, the adhesion to polyimide at 23° C. (P(23° C.)) is more preferably 3.6 N/cm or more, further preferably 3.8 N/cm or more, and particularly preferably 4.0 N/cm or more. From the same viewpoint, the adhesion to polyimide at 60° C. (P(60° C.)) is more preferably 1.6 N/cm or more, further preferably 1.7 N/cm or more, and particularly preferably 1.8 N/cm or more. The adhesion can be measured, specifically by the method in Examples described later.

Furthermore, in the present adhesive sheet, a ratio (P(23° C.)/P(60° C.)) of the adhesion to polyimide at 23° C. (P(23° C.)) to the adhesion to polyimide at 60° C. (P(60° C.)) is 0.3 to 2.6.

The adhesive sheet satisfying the above has a small temperature dependence of the adhesion and excellent adhesiveness in a wide temperature range, such that delamination hardly occurs even when a laminate bonded to an adherend such as a constituent member of an image display device is bent, and excellent durability can be achieved.

From this viewpoint, the ratio (P(23° C.)/P(60° C.)) of the adhesion to polyimide at 23° C. (P(23° C.)) to the adhesion to polyimide at 60° C. (P(60° C.)) is preferably 0.4 or more, more preferably 0.5 or more, further preferably 0.6 or more, particularly preferably 0.7 or more, and the most preferably 0.8 or more. Additionally, from the same viewpoint, an upper limit of the adhesion ratio is preferably 2.5 or less, more preferably 2.4 or less, further preferably 2.3 or less, particularly preferably 2.2 or less, and the most preferably 2.0 or less.

Moreover, from the viewpoint of stronger adherence at room temperature, the adhesion ratio is preferably 1.0 or more, more preferably 1.1 or more, further preferably 1.2 or more, and particularly preferably 1.3 or more.

In the present disclosure, the adhesion to polyimide refers to adhesion to a transparent polyimide film, which is often used for a flexible member, and can be measured by a method described in Examples.

Note that the polyimide refers to a polymer containing an imide bond in a repeating unit, and examples thereof include aromatic polyimide in which aromatic compounds are directly coupled by imide bonds, etc.

### (Recovering Ability)

In the present adhesive sheet, a recovery rate calculated by the following expression is preferably equal to or more than 60%, more preferably equal to or more than 65%, based on a thickness of 0.5 to 1.2 mm, a strain (γₘₐₓ) after applying 400% strain at a temperature of 25° C. for 600 seconds, and a strain (γₘᵢₙ) 600 seconds after stress unloading.

$$recovery rate ( \% ) = [ ( {γ}_{max} - {γ}_{min} ) / {γ}_{max} ] \times 100$$

The present adhesive sheet with such recovering ability can be an adhesive sheet excellent in flexibility with no crease left even after folding the present adhesive sheet attached to a member sheet at low or high temperatures and leaving it in the folded state. Note that the higher recovering ability is more preferable, and thus an upper limit of the recovering ability is 100%.

To impart favorable flexibility to the present adhesive sheet, it is preferable for the acrylic polymer (A) or the adhesive layer to have the structural site derived from the alkyl (meth)acrylate (a1) and the structural site derived from the hydroxyl group-containing (meth)acrylate (a2), and more preferable for the adhesive layer or the adhesive composition to include the radically polymerizable compound (D).

Preferred as the radically polymerizable compound (D) is a polymerizable compound that has an oxyalkylene structure containing an alkylene group with a length in the predetermined range. The use of such polymerizable compound having an alkylene glycol backbone makes the bonding to the acrylic polymer (A) easier, resulting in strong entanglement of polymer chains. Therefore, entropy difference before and after elongation becomes large, and the recovering ability can be improved by entropic elasticity.

However, the adjustment method of the recovering ability is not limited to these methods.

### (Gel Fraction)

A gel fraction of the present adhesive sheet is preferably 95% or less, more preferably 90% or less, and further preferably 85% or less. When the gel fraction of the present adhesive sheet is equal to or less than the numerical value, it is possible to enhance adhesion to a flexible member. Furthermore, a lower limit is preferably 30% or more, more preferably 40% or more, and particularly preferably 50% or more. When the gel fraction is equal to or more than the lower limit value, shape retention tends to be sufficiently achieved.

The gel fraction is an indicator of a degree of crosslinking (degree of curing) and can be measured under the measurement conditions in Examples described later.

### (Transparency, Haze)

The present adhesive sheet is transparent when visually observed. Transparency indicates a uniform compatible state of the respective components.

Additionally, the present adhesive sheet has a total light transmittance of preferably 80% or more, further preferably 85% or more, and particularly preferably 90% or more. The total light transmittance of the present adhesive sheet equal to or more than the numerical value tends to allow the present adhesive sheet to be suitably applied to an image display device.

Furthermore, in the present adhesive sheet, a haze is preferably 5% or less, further preferably 4% or less, and particularly preferably 1% or less.

The haze of the present adhesive sheet equal to or less than the above numerical value tends to allow the present adhesive sheet to be suitably applied to an image display device.

Note that in order to control the total light transmittance and the haze of the present adhesive sheet in the above ranges, the present adhesive sheet preferably contains no particles, such as organic particles.

### <Preferable Application of Present Adhesive Sheet>

The present adhesive sheet is suitably used for pasting together the constituent members of an image display device. Specifically, it is suitably used for pasting together members constituting a display member (may be referred to as “display member”), particularly the constituent members of a flexible image display device to be used for manufacturing a display, and is used as an adhesive sheet for the constituent member of a flexible image display device.

Note that as the constituent member of a flexible image display device, the same as those described later can be used.

### <<Laminate for Image Display Device>>

A laminate for an image display device according to an exemplary embodiment of the present disclosure (hereinafter may be referred to as “the present laminate for an image display device”) is a laminate for an image display device, configured with two constituent members of an image display device laminated via the present adhesive sheet. Furthermore, the present laminate for an image display device is preferably a laminate for a flexible image display device, configured with two constituent members of a flexible image display device laminated via the present adhesive sheet.

Regarding the constituent elements of the present laminate for an image display device, the present adhesive sheet is as described above, whereas the elements other than the adhesive sheet will be described below.

### (Constituent Member of Image Display Device)

The constituent member of an image display device, which constitutes the present laminate for an image display device, is a constituent member of a flexible image display device, for example. Examples of the constituent member of a flexible image display device include flexible displays such as an organic electroluminescence (EL) display, a cover lens (cover film), a polarizing plate, a polarizer, a retardation film, a barrier film, a viewing-angle compensating film, a luminescence improving film, a contrast improving film, a diffusing film, a semitransparent reflective film, an electrode film, a transparent conductive film, a metal mesh film, a touch sensor film, etc. Two of any one or two kinds of them may be used in combination. Examples of the combination include a combination of a flexible display and another constituent member of a flexible image display device, and a combination of a cover lens and another constituent member of a flexible image display device.

Note that the constituent member of a flexible image display device means a bendable member, specifically a repeatedly bendable member. Particularly preferred is a member that can be fixed in a curved shape with a curvature radius of 25 mm or more, specifically a member that can withstand repeated bending action with a curvature radius of less than 25 mm, more preferably less than 3 mm.

In the above configuration, examples of the main component of the constituent member of a flexible image display device include a resin sheet, glass, or the like.

Examples of the material for the resin sheet include polyester resin, cycloolefin resin, triacetyl cellulose resin, polymethyl methacrylate resin, polyurethane resin, epoxy resin, polyimide resin, aramid resin, and the like. One or more kinds of these resins can be employed. Among them, at least one kind of resin selected from a group consisting of polyester resin, cycloolefin resin, triacetyl cellulose resin, polymethyl methacrylate resin, epoxy resin, polyimide resin, aramid resin, and polyurethane resin is preferably contained in the resin sheet as the main component.

The “main component” herein refers to a component that accounts for the highest weight proportion among the constituent components of the constituent member of a flexible image display device; specifically, the one that accounts for preferably 50% by mass or more, further preferably 55% by mass or more, and particularly preferably 60% by mass or more in a resin composition (resin sheet) that forms the constituent member of a flexible image display device.

Moreover, the constituent member of a flexible image display device may be composed of thin-film glass.

In the above configuration, any one of the two constituent members of a flexible image display device, namely the first constituent member of a flexible image display device, has a tensile strength, particularly at 25° C. as measured according to ASTM D882, of preferably 10 to 900 MPa, more preferably 15 to 800 MPa, and particularly preferably 20 to 700 MPa.

One of the constituent members of a flexible image display device preferably has the tensile strength at 25° C. (ASTM D882) within the above range such that breakage is less likely to occur upon bending.

Additionally, the other constituent member of a flexible image display device, namely the second constituent member of a flexible image display device, has a tensile strength at 25° C., as measured according to ASTM D882, of preferably 10 to 900 MPa, more preferably 15 to 800 MPa, and particularly preferably 20 to 700 MPa.

The other constituent member of a flexible image display device preferably has the tensile strength at 25° C. (ASTM D882) within the above range such that breakage is less likely to occur upon bending.

Examples of the constituent member of a flexible image display device with the high tensile strength include a polyimide film, a polyester film, an aramid film, etc., each of these having a tensile strength of 900 MPa or lower in general.

On the other hand, examples of the constituent member of a flexible image display device with the slightly low tensile strength include a triacetylcellulose (TAC) film, a cycloolefin polymer (CδP) film, etc., each of these having a typical tensile strength of 10 MPa or higher.

Even when the present laminate for a flexible image display device includes the constituent member of a flexible image display device, which is composed of such a material with a slightly low tensile strength, it is possible to prevent defects such as breakage due to the action of the present adhesive sheet.

### <Method for Producing Present Laminate for Image Display Device>

A method for producing the present laminate for an image display device is not particularly limited. As described above, for example, the adhesive composition may be applied onto the constituent member of an image display device, preferably onto the constituent member of a flexible image display device to form the adhesive sheet, or the adhesive sheet is formed in advance, and then attached to the constituent member of an image display device, preferably the constituent member of a flexible image display device.

### <<Flexible Image Display Device>>

A flexible image display device according to an exemplary embodiment of the present disclosure (hereinafter may be referred to as “the present flexible image display device”) is an image display device including the incorporated laminate for a flexible image display device, where the laminate is configured with two constituent members of the flexible image display device bonded to each other via the present adhesive sheet. For example, the present flexible image display device including the laminate for a flexible image display device, configured with two constituent members of the flexible image display device bonded to each other via the present adhesive sheet can be formed by laminating the laminate on another constituent member of the image display device.

In the present disclosure, the “flexible image display device” refers to an image display device that has no folding marks left even after repeated folding, can return to its original state before folding immediately after being released from the folded state, and can display an image without distortion even when folded.

A more specific example is an image display device including a member that can have a curved fixed shape with a curvature radius of 25 mm or more, particularly a member that can withstand repeated folding action with a curvature radius of less than 25 mm, more preferably a curvature radius of less than 3 mm.

The present laminate for an image display device enables it to prevent delamination and breakage of the laminate and also has favorable recovering ability even when folded in the environment at high temperature. Accordingly, it has a feature capable of producing a flexible image display device with excellent flexibility.

### EXAMPLES

Hereinafter, the present disclosure will be described in more detail with reference to Examples and Comparative Examples.

However, the present disclosure is not limited by these examples. In the examples, “parts” means parts on a mass basis.

### <Raw Materials>

First of all, the acrylic polymer (A) and the adhesive composition prepared in Examples and Comparative Examples will be described in detail.

### <Acrylic Polymer (A)>

Acrylic copolymer (A-1): random copolymer of 2-ethylhexyl acrylate (60 parts), butyl acrylate (15 parts), ethyl methacrylate (5 parts), and 2-hydroxyethyl acrylate (20 parts) (hydroxyl value: 96 mgKOH/g, weight-average molecular weight: 940,000, glass transition temperature defined by Tan δ peak: −23° C.)

### <Photoinitiator (B)>

Photoinitiator (B-1): mixture of 4-methylbenzophenone and 2,4,6-trimethylbenzophenone (hydrogen abstraction-type) (“Esacure TZT” manufactured by IGM Resins B.V.)

### <Epoxy Compound (C)>

Polyfunctional epoxy compound (C-1): polyethylene glycol #400 diglycidyl ether [“EPOLIGHT 400E” manufactured by Kyoeisha Chemical Co., Ltd., HSP (δP: 7.5 MPa^{0.5}, δH: 8.8 MPa^{0.5})]
Polyfunctional epoxy compound (C-2): tripropylene glycol diglycidyl ether [“EPOLIGHT 200P” manufactured by Kyoeisha Chemical Co., Ltd., HSP (δP: 7.2 MPa^{0.5}, δH: 5.8 MPa^{0.5})]
Polyfunctional epoxy compound (C-3): polypropylene glycol #400 diglycidyl ether [“EPOLIGHT 400P” manufactured by Kyoeisha Chemical Co., Ltd., HSP (δP: 6.3 MPa^{0.5}, δH: 5.7 MPa^{0.5})]
Polyfunctional epoxy compound (C-4): 1,6-hexanediol diglycidyl ether [“EPOLIGHT 1600” manufactured by Kyoeisha Chemical Co., Ltd., HSP (δP: 7.6 MPa^{0.5}, δH: 5.7 MPa^{0.5})]
Monofunctional epoxy compound (C-5): C12-C13 mixed higher alcohol glycidyl ether [“EPOLIGHT M-1230” manufactured by Kyoeisha Chemical Co., Ltd., HSP (δP: 3.9 MPa^{0.5}, δH: 3.4 MPa^{0.5})]

Note that HSP (δP, δH) of the epoxy compound (C) were obtained by the Y-MB method implemented in the computer software, Hansen Solubility Parameters in Practice (HSPIP).

### <Radically Polymerizable Compound (D)>

Radically polymerizable compound (D-1): monofunctional urethane acrylate having a polypropylene glycol backbone (provided that a small amount of a bifunctional group is contained) (“PEM-X264” manufactured by AGC Inc.)

### Examples 1 to 9, Comparative Example 1

With the formulation shown in Table 1 below, the raw materials of the adhesive composition and ethyl acetate as a solvent were uniformly mixed to obtain an adhesive composition solution (solids concentration: 40% by mass).

The adhesive composition solution was coated on a release film (manufactured by Mitsubishi Chemical Corporation, polyester film subjected to silicone release treatment, thickness of 100 μm) such that the thickness after drying was 50 μm. After the coating, the resultant was placed in a dryer heated to a temperature of 90° C., and held for 7 minutes to evaporate the solvent contained in the adhesive composition to dryness.

Furthermore, on a surface of the solvent-dried adhesive composition, a laminate including a laminated release film (manufactured by Mitsubishi Chemical Corporation, polyester film subjected to silicone release treatment, thickness of 75 μm) was formed, and the adhesive composition was irradiated with ultraviolet rays through the release film by using a high-pressure mercury lamp (wavelength of 365 nm) (for integrated light intensity, see Table 1), thereby obtaining an adhesive sheet with the release film.

The adhesive sheet thus obtained was evaluated as follows. Additionally, the computer software, Hansen Solubility Parameters in Practice (HSPiP) was used to obtain an HSP distance (Ra) between the acrylic copolymer (A) and the epoxy compound (C). These results are shown in Table 1 below.

### <Storage Shear Modulus (G′), Loss Tangent (tan δ), Glass Transition Temperature (Tg)>

The release film on one side of the adhesive sheet with the release film prepared in each of Examples and Comparative Examples was removed. Then, the adhesive sheet was repeatedly laminated using a hand roller to adjust its thickness to about 0.8 mm and punched into a circle with a diameter of 8 mm, thereby preparing a sample. The sample thus obtained was installed on a rheometer (“DHR-2” manufactured by T. A. Instruments), dynamic viscoelasticity measurement was performed using an 8-mm-diameter parallel-plate as a measuring instrument at a frequency of 1 Hz, a measurement temperature of −50 to 80° C., and a temperature rise rate of 5° C./min, and values of storage shear modulus (G′) at −30 to 80° C. and values of loss tangent (tan δ) at 25 to 60° C. were read.

Additionally, from the obtained temperature distribution data of the dynamic viscoelasticity, a temperature of a maximum point of the loss tangent (tan δ) was read as the glass transition temperature (Tg).

### <Adhesion to Polyimide (CPI)>

The release film on one side of the adhesive sheet with the release film prepared in each of the Examples and Comparative Examples was removed, and a PET film (manufactured by Mitsubishi Chemical Corporation, Diafilm S-100, thickness of 50 μm) was bonded thereto as a lining film using a hand roller. This was cut into a strip shape with a width of 10 mm and a length of 150 mm, and an adhesive surface exposed by peeling off the remaining release film was bonded to a transparent polyimide (CPI) film (“C_50” manufactured by KOLON Industries), which was bonded to a SUS plate in advance, by a hand roller, thereby preparing an adhesion measurement sample. By pulling the adhesion measurement sample thus obtained at 23° C. and 60° C. at an angle of 180° and a peel speed of 300 mm/min, the adhesive sheet together with the lining film were peeled off from the CPI film to measure the tensile strength (N/cm) by a load cell, thereby obtaining the adhesion to polyimide at 23° C. (P(23° C.)) and the adhesion to polyimide at 60° C. (P(60° C.)).

Based on the measured adhesion to polyimide, the ratio (P(23° C.)/P(60° C.)) of the adhesion to polyimide at 23° C. to the adhesion to polyimide at 60° C. was obtained.

### <Creep Test>

The release film on one side of the adhesive sheet with the release film prepared in each of the Examples and Comparative Examples was removed. Then, the adhesive sheet was repeatedly laminated by using a hand roller to adjust its thickness to about 0.8 mm and punched into a circle with a diameter of 8 mm, thereby preparing a sample.

For this sample, a dynamic viscoelasticity measurement device (“DHR2” manufactured by T. A. Instruments,) was used to read a maximum strain value (γₘₐₓ) after applying 400% strain at a temperature of 25° C. for 600 seconds, and a residual strain value (γₘᵢₙ) 600 seconds after stress unloading.

### <Recovering Ability>

A recovery rate was obtained by plugging the maximum strain value (γₘₐₓ) and the residual strain value (γₘᵢₙ) obtained in the creep test into the following expression.

$$recovery rate ( \% ) = [ ( {γ}_{max} - {γ}_{min} ) / {γ}_{max} ] \times 100$$

### <Gel Fraction>

The release film was removed from the adhesive sheet with the release film prepared in each of the Examples and Comparative Examples, thereby preparing a sample.

This sample was wrapped in a 150-mesh SUS gauze and immersed in ethyl acetate for 24 hours. Thereafter, it was dried at 70° C. for 4.5 hours, the mass of the adhesive sheet before and after the immersion in ethyl acetate was respectively measured, and the mass difference between them was taken as the mass of the insoluble adhesive sheet remaining in the gauze. The mass percentage of the insoluble adhesive sheet remaining in the gauze relative to the mass of the adhesive sheet before the immersion in ethyl acetate was calculated as the gel fraction (%).

TABLE 1

| | | | | | | | | | | | | | | Comp. |
|---|---|---|---|---|---|---|---|---|---|---|---|---|---|---|
| | | | | | Ex. | Ex. | Ex. | Ex. | Ex. | Ex. | Ex. | Ex. | Ex. | Ex. |
| | | | | | 1 | 2 | 3 | 4 | 5 | 6 | 7 | 8 | 9 | 1 |
| Adhesive | Acrylic polymer (A) | | A-1 | parts | 100 | 100 | 100 | 100 | 100 | 100 | 100 | 100 | 100 | 100 |
| compo- | Photoinitiator (B) | | B-1 | parts | 3 | 3 | 3 | 3 | 3 | 3 | 3 | 3 | 3 | 3 |
| sition | Epoxy | poly- | C-1 | parts | 0.05 | 0.10 | 0.20 | 0.20 | 1.00 | — | — | — | — | — |
| | compound | func- | C-2 | parts | — | — | — | — | — | 0.10 | — | — | — | — |
| | (C) | tional | C-3 | parts | — | — | — | — | — | — | 0.10 | — | — | — |
| | | | C-4 | parts | — | — | — | — | — | — | — | 0.10 | — | — |
| | | mono- | C-5 | parts | — | — | — | — | — | — | — | — | 0.10 | — |
| | | func- | | | | | | | | | | | | |
| | | tional | | | | | | | | | | | | |

| | Radically | D-1 | parts | 50 | 50 | 50 | 50 | 50 | 50 | 50 | 50 | 50 | 50 |
|---|---|---|---|---|---|---|---|---|---|---|---|---|---|
| | polymerizable | | | | | | | | | | | | |
| | compound (D) | | | | | | | | | | | | |
| Adhesive | Thickness | | μm | 50 | 50 | 50 | 50 | 50 | 50 | 50 | 50 | 50 | 50 |
| sheet | Integrated light | | J/cm² | 1.0 | 1.0 | 1.0 | 0.6 | 1.0 | 1.0 | 1.0 | 1.0 | 1.0 | 1.0 |
| | intensity | | | | | | | | | | | | |
| | (wavelength: 365 nm) | | | | | | | | | | | | |
| | HSP distance | | | 4.1 | 4.1 | 4.1 | 4.1 | 4.1 | 3.4 | 2.8 | 3.7 | 2.9 | — |
| | Storage | −30° C. | kPa | 446 | 521 | 456 | 415 | 385 | 421 | 454 | 472 | 413 | 476 |
| | shear | −20° C. | kPa | 204 | 218 | 209 | 180 | 168 | 180 | 207 | 192 | 1 [symbol] 5 | 191 |
| | modulus | 25° C. | kPa | 52 | 5 [symbol] | 50 | 41 | 40 | 43 | 47 | 47 | 43 | 46 |
| | (G′) | 60° C. | kPa | 37 | 35 | 35 | 27 | 27 | 30 | 33 | 33 | 29 | 32 |
| | | 80° C. | kPa | 33 | 31 | 31 | 23 | 23 | 28 | 2 [symbol] | 29 | 25 | 27 |
| | Loss tangent | 25° C. | — | 0.27 | 0.29 | 0.2 [symbol] | 0.32 | 0.32 | 0.29 | 0.23 | 0.29 | 0.31 | 0.2 [symbol] |
| | (tanδ) | 60° C. | — | 0.22 | 0.24 | 0.22 | 0.2 [symbol] | 0.27 | 0.24 | 0.24 | 0.23 | 0.27 | 0.23 |
| | Glass | tanδ | ° C. | −41 | −3 [symbol] | −41 | −41 | −41 | −40 | −39 | −41 | −41 | −40 |
| | transition | peak | | | | | | | | | | | |
| | temperature | | | | | | | | | | | | |
| | Adhesion to | 23° C. | N/cm | 4.3 | 4.5 | 4.6 | 5.2 | 3.7 | 3. [symbol] | 4.0 | 3.6 | 3.4 | 3.7 |
| | polyimide (P) | 60° C. | N/cm | 2.2 | 2.7 | 2.6 | 2.4 | 2.2 | 1.7 | 1.8 | 1.7 | 1.6 | 1.4 |

| P (23° C.)/P | | — | 1.9 [symbol] | 1.65 | 1.75 | 2.13 | 1. [symbol] 8 | 2.19 | 2.16 | 2.19 | 2.1 [symbol] | 2.64 |
|---|---|---|---|---|---|---|---|---|---|---|---|---|
| (60° C.) | | | | | | | | | | | | |
| Creep test | Recovery rate | % | 67 | 74 | 62 | 75 | 85 | 63 | 56 | 69 | 68 | 57 |

| | | | | | | | | | | | |
|---|---|---|---|---|---|---|---|---|---|---|---|
| Gel fraction | % | 84.3 | [symbol] 4.6 | 84.0 | 75.7 | 80.9 | [symbol] 3.8 | [symbol] .7 | 82.9 | 83.0 | 84.1 |
| Total light | % | 92 | 92 | 92 | 92 | 92 | 92 | 92 | 92 | 92 | 92 |
| transmittance | | | | | | | | | | | |
| Haze | % | 0.3 | 0.2 | 0.3 | 0.5 | 0.2 | 0.3 | 0.3 | 0.3 | 0.3 | 0.3 |

[symbol]

indicates data missing or illegible when filed

The adhesive sheets in Examples 1 to 9 were formed from the adhesive composition including the acrylic copolymer (A) containing no carboxy group, the photoinitiator (B), and the epoxy compound (C), and had the storage shear modulus at 25° C. in a specific range, so that they had excellent adhesiveness to a flexible member as well as excellent flexibility.

Additionally, the adhesive sheets in Examples 1 to 9 were formed from the adhesive composition including the acrylic copolymer (A) containing no carboxy group, the photoinitiator (B), and the epoxy compound (C), and had the ratio of adhesion to polyimide between 23° C. and 60° C. in a specific range, so that they had excellent adhesiveness to a flexible member as well as excellent flexibility.

On the other hand, the adhesive sheet containing no epoxy compound (C) in Comparative Example 1 was inferior in adhesiveness to a flexible member at high temperature.

It should be noted that specific embodiments of the present disclosure have been described in the Examples above, but Examples are for illustrative purposes only and are not to be construed as limitative. It is intended that various modifications apparent to a person skilled in the art fall within the scope of the present disclosure.

### INDUSTRIAL APPLICABILITY

The adhesive sheet of the present disclosure is excellent in adhesion to a flexible member and also has flexibility. Accordingly, it is useful as an adhesive sheet for obtaining various flexible image display devices, such as bendable, foldable, rollable, or stretchable image display devices, and particularly suitable as an adhesive sheet for a foldable image display device which will be repeatedly folded

1. An adhesive sheet formed from an adhesive composition comprising an acrylic polymer (A) containing no carboxy group, a photoinitiator (B), and an epoxy compound (C).

2. The adhesive sheet according to claim 1, wherein the adhesive sheet has a storage shear modulus at 25° C. (G′ (25° C.)) equal to or less than 60 kPa as determined by dynamic viscoelasticity measurement with a shearing mode at a frequency of 1 Hz.

3. The adhesive sheet according to claim 1, wherein the adhesive sheet has a ratio (P(23° C.)/P(60° C.)) of adhesion to polyimide at 23° C. (P(23° C.)) to adhesion to polyimide at 60° C. (P(60° C.)) of 0.3 to 2.6.

4. The adhesive sheet according to claim 3, wherein the adhesion to polyimide at 23° C. (P(23° C.)) is equal to or more than 3.5 N/cm, and the adhesion to polyimide at 60° C. (P(60° C.)) is equal to or more than 1.5 N/cm.

5. The adhesive sheet according to claim 1, wherein in Hansen solubility parameters (δD, δP, δH), a Hansen solubility parameter distance (Ra) between Hansen solubility parameters of the epoxy compound (C) and Hansen solubility parameters of the acrylic polymer (A) containing no carboxy group is 2.0 to 10.0.

6. The adhesive sheet according to claim 1, wherein the epoxy compound (C) has a polar term δP equal to or more than 4.5 MPa^{0.5}, and a hydrogen bond term δH equal to or more than 4.0 MPa^{0.5} in Hansen solubility parameters (δD, δP, δH) calculated by a Y-MB method.

7. The adhesive sheet according to claim 1, wherein the epoxy compound (C) includes a polyfunctional epoxy compound.

8. The adhesive sheet according to claim 1, wherein the epoxy compound (C) includes an epoxy compound comprising an alkylene glycol backbone.

9. The adhesive sheet according to claim 1, wherein the epoxy compound (C) includes an epoxy compound comprising an alkylene glycol backbone, the number of repeating units thereof being 2 to 30.

10. The adhesive sheet according to claim 1, wherein the epoxy compound (C) includes an epoxy compound comprising a linear alkylene glycol backbone.

11. The adhesive sheet according to claim 1, wherein the epoxy compound (C) includes an epoxy compound having a weight-average molecular weight of 200 to 1000.

12. The adhesive sheet according to claim 1, wherein the epoxy compound (C) includes an epoxy compound having an epoxy equivalent weight of 80 to 500.

13. The adhesive sheet according to claim 1, wherein the epoxy compound (C) is contained in an amount of 0.01 to 10 parts by mass relative to 100 parts by mass of the acrylic polymer (A) containing no carboxy group.

14. The adhesive sheet according to claim 1, wherein the adhesive composition comprises a radically polymerizable compound (D).

15. The adhesive sheet according to claim 14, wherein the radically polymerizable compound (D) comprises an alkylene glycol backbone.

16. The adhesive sheet according to claim 14, wherein the radically polymerizable compound (D) comprises a urethane bond.

17. The adhesive sheet according to claim 1, comprising a hydrogen abstraction-type photoinitiator (b1) as the photoinitiator (B).

18. The adhesive sheet according to claim 1, wherein the acrylic polymer (A) containing no carboxy group comprises an acrylic polymer comprising a structural site derived from a (meth)acrylate (a1) comprising an alkyl group having 3 or more carbon atoms, and a structural site derived from a hydroxyl group-containing (meth)acrylate (a2).

19. The adhesive sheet according to claim 1, wherein the adhesive sheet has a storage shear modulus at −30° C. (G′(−30° C.)) equal to or less than 1200 kPa as determined by dynamic viscoelasticity measurement with a shearing mode at a frequency of 1 Hz.

20. The adhesive sheet according to claim 1, wherein the adhesive sheet has a glass transition temperature (Tg) equal to or lower than −20° C., the glass transition temperature (Tg) being defined by a maximum value of Tan δ as determined by dynamic viscoelasticity measurement with a shearing mode at a frequency of 1 Hz.

21. The adhesive sheet according to claim 1, wherein the adhesive sheet has a recovery rate equal to or more than 60% calculated by the following expression based on a thickness of 0.5 to 1.2 mm, a strain (γₘₐₓ) after applying 400% strain at a temperature of 25° C. for 600 seconds, and a strain (γₘᵢₙ) 600 seconds after stress unloading.
$$recovery rate ( \% ) = [ ( {γ}_{max} - {γ}_{min} ) / {γ}_{max} ] \times 100$$

22. The adhesive sheet according to claim 1, wherein the adhesive sheet has a gel fraction of 30 to 95%.

23. The adhesive sheet according to claim 1, wherein the adhesive sheet has a total light transmittance equal to or more than 80% and a Haze equal to or less than 5%.

24. An adhesive sheet with a release film, comprising the adhesive sheet according to claim 1 and a release film, wherein the adhesive sheet and the release film are laminated together.

25. A laminate for an image display device, comprising two constituent members of an image display device and the adhesive sheet according to claim 1, wherein the two constituent members of an image display device are laminated via the adhesive sheet.

26. A flexible image display device comprising the laminate for an image display device according to claim 25.

27. An adhesive sheet for a constituent member of a flexible image display device, comprising the adhesive sheet according to claim 1.
